(19) United States
(12) Patent Application Publication
(10) Pub. No.: US 2025/0311327 A1
(43) Pub. Date: Oct. 2, 2025

(54) METHOD FOR MANUFACTURING SEMICONDUCTOR DEVICE HAVING COMPLEMENTARY FIELD-EFFECT TRANSISTOR STRUCTURE

(71) Applicant: TAIWAN SEMICONDUCTOR MANUFACTURING COMPANY, LTD., Hsinchu (TW)

(72) Inventors: Tze-Chung LIN, Hsinchu (TW); Fang-Wei LEE, Hsinchu (TW); Chia-Hao YU, Hsinchu (TW); Putikam RAGHUNATH, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 18/617,303

(22) Filed: Mar. 26, 2024

(51) Int. Cl. H01L 29/06; H01L 21/8234; H01L 27/088; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017; H10D 64/018; H10D 84/0128; H10D 84/013; H10D 84/0135; H10D 84/0151; H10D 84/038; H10D 84/83

(57) ABSTRACT

A method for manufacturing a semiconductor device includes: forming a plurality of stack portions spaced apart from each other by a plurality of source/drain trenches. Each of the stack portions includes a set of channel features and a set of sacrificial features disposed to alternate with the set of the channel features. Each sacrificial feature of the set of the sacrificial features has an etching selectivity greater than that of each channel feature of the set of the channel features. At least one sacrificial feature of the set of the sacrificial features includes an n-type dopant, a p-type dopant, an impurity, or combinations thereof so as to permit one intermediate sacrificial feature of the set of the sacrificial features to have an etching selectivity greater than that of the other sacrificial features of the set of the sacrificial features.

### BACKGROUND

Emergence of complementary field-effect transistors (CFETs) presents a prospective solution for extending the prediction of Moore's law, and caters to an increasing demand on FETs with an improved transistor performance and a reduced power consumption. At present, CFET may have a vertically stacked structure including an n-type FET and a p-type FET. Despite an anticipated rise in the complexity and cost of a manufacturing process of the CFET, the vertically stacked structure of the CFET is a promising device architecture and has been attracted much attention in the semiconductor industry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2A to 8 are schematic views illustrating some intermediate stages of the method as depicted in FIG. 1 in accordance with some embodiments.

FIGS. 9 to 10C are schematic views illustrating some intermediate stages of the method as depicted in FIG. 1 in accordance with some embodiments.

FIG. 11 is a schematic view of a structure in an intermediate stage of the method as depicted in FIG. 1 in accordance with some embodiments.

FIGS. 12A to 14C are schematic views illustrating some intermediate stages of the method as depicted in FIG. 1 for forming the structure shown in FIG. 11 in accordance with some embodiments.

FIGS. 15 to 18 are schematic views respectively illustrating different doping configuration of a nanosheet stack in an intermediate stage of the method as depicted in FIG. 1 in accordance with some embodiments.

FIG. 19 is a schematic view of a structure in an intermediate stage of the method as depicted in FIG. 1 in accordance with some embodiments.

FIGS. 20 to 22 are schematic views illustrating intermediate stages of the method as depicted in FIG. 1 for forming the structure shown in FIG. 19 in accordance with some embodiments.

FIG. 23 is a schematic view illustrating a semiconductor device obtained by the method as depicted in FIG. 1 in accordance with some embodiments.

FIG. 24 is a schematic view of a structure in an intermediate stage of the method as depicted in FIG. 1 in accordance with some embodiments.

FIGS. 25 to 27 are schematic views illustrating intermediate stages of the method as depicted in FIG. 1 for forming the structure shown in FIG. 24 in accordance with some embodiments.

FIG. 28 is a schematic view illustrating a semiconductor device obtained by the method as depicted in FIG. 1 in accordance with some embodiments.

FIG. 29 is a schematic view illustrating diffusion of dopants in a semiconductor device in accordance with some embodiments.

FIG. 30 is a schematic view of a structure in an intermediate stage of the method as depicted in FIG. 1 in accordance with some embodiments.

FIG. 31 is a schematic view of a structure formed by subjecting the structure shown in FIG. 30 to an etching process in accordance with some embodiments.

FIG. 32 is a schematic view illustrating a partially enlarged portion of a structure formed by subjecting the structure shown in FIG. 7 to an etching process.

FIG. 33 is a schematic view illustrating a partially enlarged portion of a structure formed by subjecting the structure shown in FIG. 11 to an etching process.

FIG. 34 is a schematic view illustrating a partially enlarged portion of the structure shown in FIG. 31.

FIG. 35 is a schematic view of a structure in an intermediate stage of the method as depicted in FIG. 1 in accordance with some embodiments.

FIGS. 36 to 40 are schematic views illustrating intermediate stages of the method as depicted in FIG. 1 for forming the structure shown in FIG. 35 in accordance with some embodiments.

FIGS. 41 and 42 are schematic views illustrating some intermediate stages of the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

With continuous advancement of semiconductor technology, various three dimensional (3D) transistor structures (e.g., a gate-all-around field-effect transistor (GAAFET) structure, a forksheet field-effect transistor structure, a complementary field effect transistor (CFET) structure including stacked transistors, etc.) are developed for manufacturing an integrated circuit (IC) with a high integration density. In particular, the CFET structure is a promising candidate in advanced logic IC technology among the 3D transistor structures. In a current manufacturing process of a CFET structure in a nanosheet semiconductor device, source/drain portions of the CFET structure may be damaged in some etching processes (e.g., sheet formation process, etc.), which may adversely affect device performance and production yield of the nanosheet semiconductor device. In order to avoid damage to the source/drain portions of the CFET structure, there is a need to improve the current manufacturing process of the CFET structure.

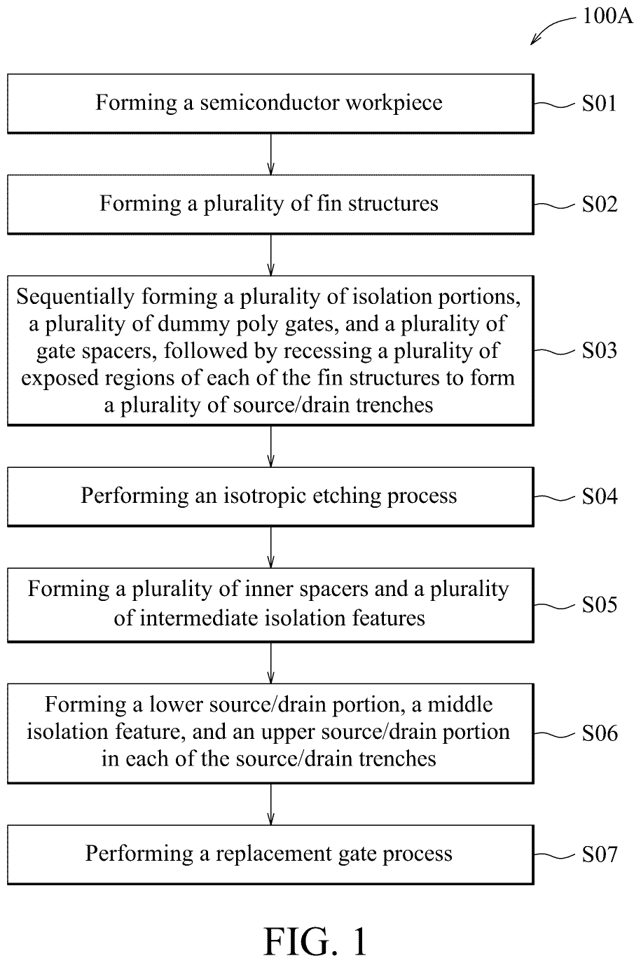

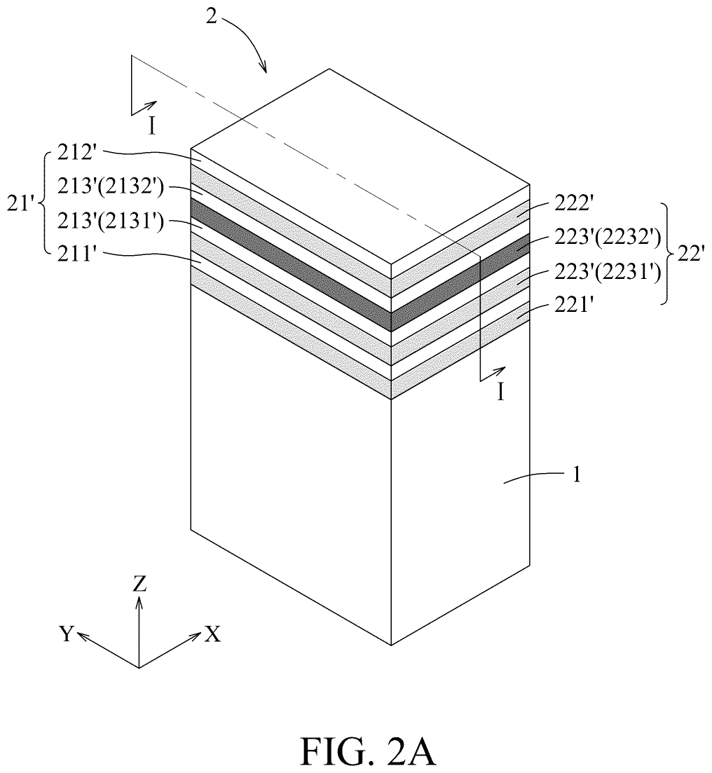

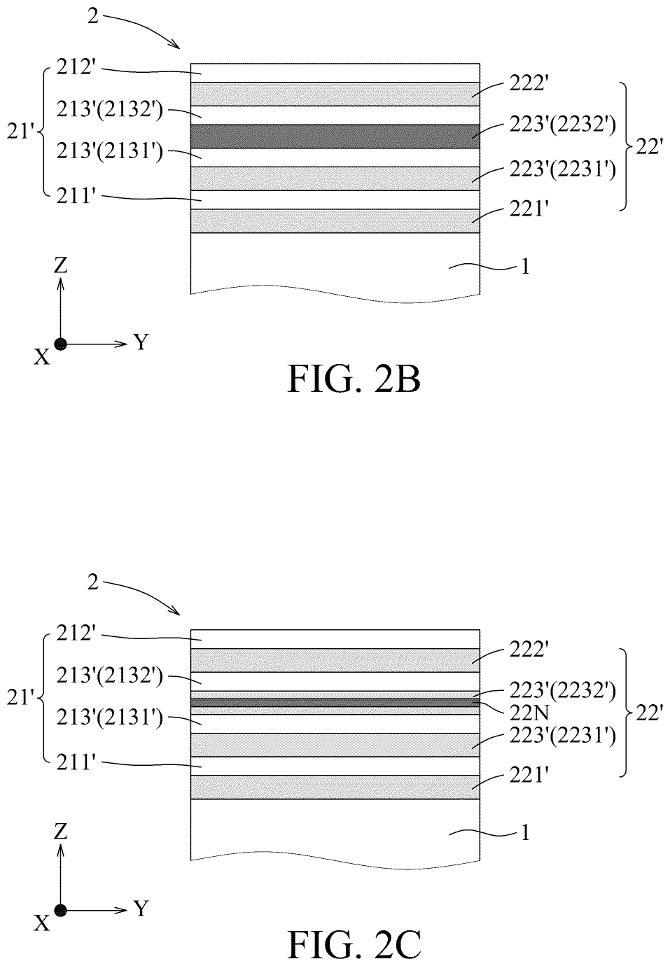

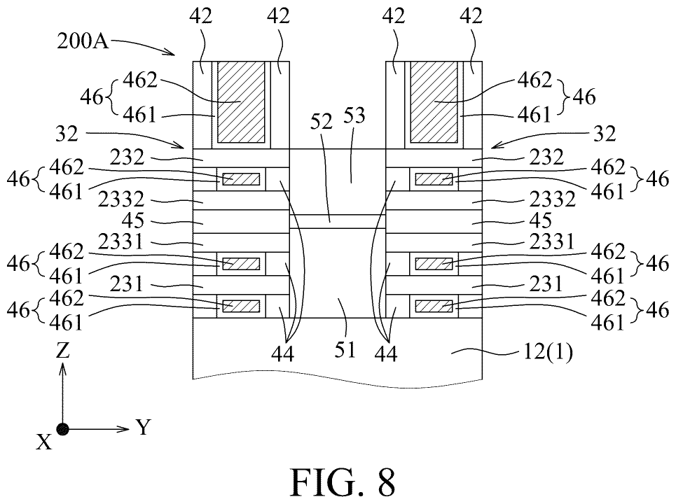

The present disclosure is directed to a semiconductor device and a method for manufacturing the same. FIG. 1 is a flow diagram illustrating a method 100A for manufacturing a semiconductor device 200A shown in FIG. 8 in accordance with some embodiments. FIGS. 2A to 7 illustrate schematic views of some intermediate stages of the method 100A. Some portions may be omitted in FIGS. 2A to 7 for the sake of brevity. Additional steps can be provided before, after or during the method 100A, and some of the steps described herein may be replaced by other steps or be eliminated.

Referring to FIG. 1 and the example illustrated in FIGS. 2A to 2C, the method 100A begins at step S01, where a semiconductor workpiece is formed. FIG. 2B illustrates a cross-sectional view taken along line I-I of FIG. 2A. The semiconductor workpiece includes a semiconductor substrate 1 and a nanosheet stack 2.

The semiconductor substrate 1 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 1 may include a multilayer compound semiconductor structure. In some embodiments, the semiconductor substrate 1 may be a semiconductor on insulator (SOI) (e.g., silicon germanium on insulator (SGOI)). Generally, an SOI substrate includes a layer of a semiconductor material, such as epitaxial silicon (Si), germanium (Ge), silicon germanium (SiGe), or combinations thereof. The SOI substrate may be doped with a p-type dopant, for example, but not limited to, boron (B), aluminum (Al), or gallium (Ga). Other suitable p-type dopant materials are within the contemplated scope of the present disclosure. Alternatively, the SOI substrate may be doped with an n-type dopant, for example, but not limited to, nitrogen (N), phosphorous (P), or arsenic (As). Other suitable n-type dopant materials are within the contemplated scope of the present disclosure.

The nanosheet stack 2 is disposed on the semiconductor substrate 1 in a Z direction normal to the semiconductor substrate 1. The nanosheet stack 2 includes a first set of layers 21′ and a second set of layers 22′. The first set of layers 21′ includes a lowermost channel layer 211′, an uppermost channel layer 212′, and at least one intermediate channel layer 213′ which is disposed between and spaced apart from the lowermost channel layer 211′ and the uppermost channel layer 212′. The second set of layers 22′ includes a lowermost sacrificial layer 221′, an uppermost sacrificial layer 222′, and at least one intermediate sacrificial layer 223′ which is disposed between and spaced apart from the lowermost sacrificial layer 221′ and the uppermost sacrificial layer 222′. The first set of layers 21′ are disposed to alternate with the second set of layers 22′ in the Z direction. The lowermost sacrificial layer 221′ is disposed on the semiconductor substrate 1. In some embodiments, the at least one intermediate channel layer 213′ includes a first intermediate channel layer 2131′ and a second intermediate channel layer 2132′. In some embodiments, the at least one intermediate sacrificial layer 223′ includes a first intermediate sacrificial layer 2231′ and a second intermediate sacrificial layer 2232′, which are disposed to alternate with the first intermediate channel layer 2131′ and the second intermediate channel layer 2132′. In this case, the first intermediate sacrificial layer 2231′ is disposed between the lowermost channel layer 211′ and the first intermediate channel layer 2131′, and the second intermediate sacrificial layer 2232′ is disposed between the first intermediate channel layer 2131′ and the second intermediate channel layer 2132′.

In some embodiments, the nanosheet stack 2 is a stack of semiconductor materials. In some embodiments, the first set of layers 21′, which includes, for example, but not limited to, the lowermost channel layer 211′, the uppermost channel layer 212′, the first intermediate channel layer 2131′, and the second intermediate channel layer 2132′, is made of a first semiconductor material; and the second set of layers 22′, which includes, for example, but not limited to, the lowermost sacrificial layer 221′, the uppermost sacrificial layer 222′, the first intermediate sacrificial layer 2231′, and the second intermediate sacrificial layer 2232′, is made of a material based on a second semiconductor material that is different from the first semiconductor material, so that each layer of the second set of layers 22′ has an etching selectivity (or an etching rate) different from that of each layer of the first set of layers 21′. In some embodiments, the first semiconductor material may be silicon, and the second semiconductor material may be silicon germanium, so that each layer of the second set of layers 22′ has an etching selectivity (or an etching rate) greater than that of each layer of the first set of layers 21′. In some embodiments, the nanosheet stack 2 may be formed on the semiconductor substrate 1 by a suitable deposition process (for example, but not limited to, chemical vapor deposition (CVD), atomic layer deposition (ALD), etc.), a suitable epitaxial growth process (for example, but not limited to, molecular beam epitaxy (MBE), selective epitaxial growth (SEG) process, etc.), or other suitable processes.

In some embodiments, at least one layer of the second set of layers 22′ is doped with an n-type dopant, a p-type dopant, an impurity, or combinations thereof so as to permit one intermediate sacrificial layer 223′ of the second set of layers 22′ to have an etching selectivity (or an etching rate) greater than that of each of the other layers of the second set of layers 22′. In some embodiments, the n-type dopant, the p-type dopant, or the impurity may be introduced into the at least one layer of the second set of layers 22′ through a doping process, an implantation process, or a combination thereof. In some embodiments, the doping process is performed to introduce the n-type dopant, the p-type dopant, or the impurity into the at least one layer of the second set of layers 22′ during formation of the at least one layer of the second set of layers 22′. In some embodiments, the implantation process is performed to introduce the n-type dopant, the p-type dopant, or the impurity into the at least one layer of the second set of layers 22′ after formation of the at least one layer of the second set of layers 22′.

In some embodiments, the n-type dopant may be, for example, but not limited to, phosphorus (P), arsenic (As), antimony (Sb), or combinations thereof. Other suitable n-type dopants are within the contemplated scope of the present disclosure. In some embodiments, the p-type dopant may be, for example, but not limited to, boron (B), aluminum (Al), gallium (Ga), indium (In), or combinations thereof. Other suitable p-type dopants are within the contemplated scope of the present disclosure. In some embodiments, the impurity may be, for example, but not limited to, carbon (C), nitrogen (N), oxygen (O), or combinations thereof. Other suitable impurities are within the contemplated scope of the present disclosure.

As shown in FIG. 2B, in some embodiments, each of the lowermost sacrificial layer 221′, the uppermost sacrificial layer 222′, the first intermediate sacrificial layer 2231′, and the second intermediate sacrificial layer 2232′ in the second set of layers 22′ includes silicon germanium having a same germanium concentration, and the second intermediate sacrificial layer 2232′ is doped with the n-type dopant, while the lowermost sacrificial layer 221′, the uppermost sacrificial layer 222′ and the first intermediate sacrificial layer 2231′ are undoped, so that the second intermediate sacrificial layer 2232′ has an etching selectivity (or an etching rate) greater than that of each of the lowermost sacrificial layer 221′, the uppermost sacrificial layer 222′ and the first intermediate sacrificial layer 2231′. In this case, the introduced n-type dopant is uniformly distributed in the second intermediate sacrificial layer 2232′. In some embodiments, the etching selectivity of the second intermediate sacrificial layer 2232′ with respect to each of the lowermost sacrificial layer 221′, the uppermost sacrificial layer 222′ and the first intermediate sacrificial layer 2231′ may range from about 1 to about 50. In some embodiments, the etching selectivity of the second intermediate sacrificial layer 2232′ with respect to each of the lowermost sacrificial layer 221′, the uppermost sacrificial layer 222′ and the first intermediate sacrificial layer 2231′ may be modified by changing a doping concentration of the n-type dopant, the germanium concentration, or a combination thereof.

As shown in FIG. 2C, in some embodiments, the introduced n-type dopant is formed as an n-type sacrificial sublayer 22N in the second intermediate sacrificial layer 2232′. In some embodiments, the n-type sacrificial sublayer 22N is located in the middle of the second intermediate sacrificial layer 2232′. Other locations for the n-type sacrificial sublayer 22N in the second intermediate sacrificial layer 2232′ are within the contemplated scope of the present disclosure.

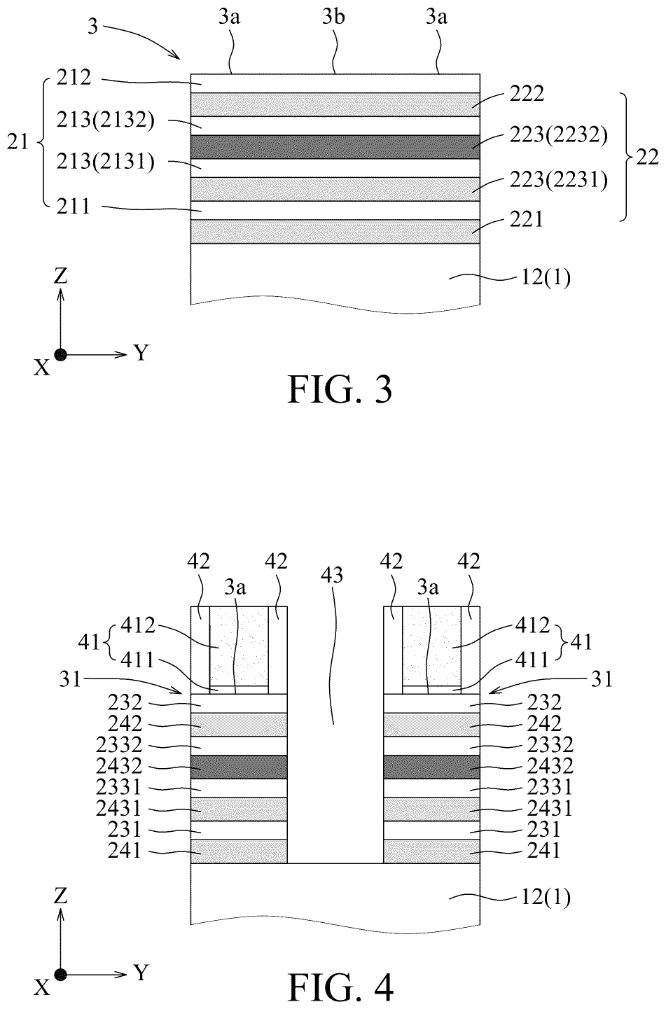

Referring to FIG. 1 and the example illustrated in FIG. 3, the method 100A then proceeds to step S02, where the semiconductor workpiece is patterned to form a plurality of fin structures 3 that extend in a Y direction transverse to the Z direction and parallel to the semiconductor substrate 1, and that are spaced apart from one another by trenches (not shown) in an X direction transverse to the Z direction and the Y direction. One of the fin structures 3 is shown in FIG. 3. Step S02 may be performed by a photolithography process, which includes an etching process. The etching process may be performed using, for example, but not limited to, an anisotropically etching process (for example, dry etching or other suitable anisotropically etching processes). After this step, the semiconductor substrate 1 is formed into a lower portion (not shown) and a plurality of fin portions 12 that are disposed on the lower portion and that are spaced apart from one another in the X direction. Each of the fin structures 3 is disposed on a corresponding one of the fin portions 12 of the semiconductor substrate 1, and includes a first set of layer portions 21 and a second set of layer portions 22 disposed to alternate with the first set of layer portions 21 in the Z direction. The first set of layer portions 21 includes a lowermost channel layer portion 211, an uppermost channel layer portion 212, and at least one intermediate channel layer portion 213 which is disposed between and spaced apart from the lowermost channel layer portion 211 and the uppermost channel layer portion 212. The lowermost channel layer portion 211, the uppermost channel layer portion 212, and the at least one intermediate channel layer portion 213 are respectively formed from the lowermost channel layer 211′, the uppermost channel layer 212′, and the at least one intermediate channel layer 213′ of the structure shown in FIGS. 2A and 2B. The second set of layer portions 22 includes a lowermost sacrificial layer portion 221, an uppermost sacrificial layer portion 222, and at least one intermediate sacrificial layer portion 223 which is disposed between and spaced apart from the lowermost sacrificial layer portion 221 and the uppermost sacrificial layer portion 222. The lowermost sacrificial layer portion 221, the uppermost sacrificial layer portion 222, and the at least one intermediate sacrificial layer portion 223 are respectively formed from the lowermost sacrificial layer 221′, the uppermost sacrificial layer 222′, and the at least one intermediate sacrificial layer 223′ of the structure shown in FIGS. 2A and 2B. In some embodiments, the at least one intermediate channel layer portion 213 includes a first intermediate channel layer portion 2131 (formed from the first intermediate channel layer 2131′) and a second intermediate channel layer portion 2132 (formed from the second intermediate channel layer 2132′). In some embodiments, the at least one intermediate sacrificial layer portion 223 includes a first intermediate sacrificial layer portion 2231 and a second intermediate sacrificial layer portion 2232, which are disposed to alternate with the first intermediate channel layer portion 2131 and the second intermediate channel layer portion 2132. In this case, the first intermediate sacrificial layer portion 2231 is disposed between the lowermost channel layer portion 211 and the first intermediate channel layer portion 2131, and the second intermediate sacrificial layer portion 2232 is disposed between the first intermediate channel layer portion 2131 and the second intermediate channel layer portion 2132.

In some embodiments, an upper surface of each of the fin structures 3 may have a plurality of covered regions 3a and a plurality of exposed regions 3b that are separated from one another in the Y direction. Two of the covered regions 3a and one of the exposed regions 3b are shown in FIG. 3.

Referring to FIG. 1 and the example illustrated in FIG. 4, the method 100A then proceeds to step S03, where a plurality of isolation portions (not shown), a plurality of dummy poly gates 41 and a plurality of gate spacers 42 are sequentially formed on the structure shown in FIG. 3, followed by recessing the exposed regions 3b of each of the fin structures 3. Step S03 may include sub-steps (i) to (iv).

In sub-step (i) of step S03, the isolation portions are formed on the lower portion of the semiconductor substrate 1. Each pair of the isolation portions is located at two opposite sides of a corresponding one of the fin portions 12 of the semiconductor substrate 1 so as to separate and isolate the fin structures 3 (see FIG. 3) from each other. The two opposite sides of the corresponding one of the fin portions 12 are opposite to each other in the X direction. In some embodiments, the isolation portions may be made of an oxide-based material (e.g., silicon oxide), a nitride-based material (e.g., silicon nitride), or a combination thereof. Other suitable materials for the isolation portions are within the contemplated scope of the present disclosure. In some embodiments, the isolation portions may be formed by a suitable deposition process, for example, but not limited to, CVD, physical vapor deposition (PVD), or other suitable deposition processes. In some embodiments, each of the isolation portions may be a portion of a shallow trench isolation (STI), a deep trench isolation (DTI), or other suitable isolation structures.

In sub-step (ii) of step S03, the dummy poly gates 41 are formed on the isolation portions and over the fin structures 3, and are spaced apart from each other in the Y direction. In some embodiments, each of the dummy poly gates 41 may include a dummy gate dielectric 411 and a dummy gate electrode 412.

The dummy gate dielectric 411 of each of the dummy poly gates 41 is disposed on a corresponding one of the covered regions 3a of each of the fin structures 3. The dummy gate dielectric 411 may be made of an oxide-based material (e.g., silicon oxide). Other suitable materials for the dummy gate dielectric 411 are within the contemplated scope of the present disclosure.

The dummy gate electrode 412 is disposed on the dummy gate dielectric 411. The dummy gate electrode 412 may include polysilicon. Other suitable materials for the dummy gate electrode 412 are within the contemplated scope of the present disclosure.

In sub-step (iii) of step S03, each pair of the gate spacers 42 is respectively formed at two opposite sides of a corresponding one of the dummy poly gates 41 in the Y direction. In some embodiments, each of the gate spacers 42 may be formed as a single layer structure or a multi-layered structure. Sub-step (iii) may be performed by depositing a spacer material layer on the dummy poly gates 41 and the exposed regions 3b (see FIG. 3) of the fin structures 3 by a suitable deposition process, for example, but not limited to, CVD, ALD, or other suitable deposition processes, followed by conducting an anisotropic dry etching process until portions of the spacer material layer, which are respectively formed on the exposed regions 3b of the fin structures 3 and an upper surface of each of the dummy poly gates 41, are removed such that remaining portions of the spacer material layer serve as the gate spacers 42. The spacer material layer for the gate spacers 42 may include, for example, but not limited to, silicon oxide, silicon nitride, silicon oxynitride, silicon carbon nitride, silicon oxycarbonnitride, or low dielectric constant (k) materials. Other suitable materials for the gate spacers 42 are within the contemplated scope of the present disclosure.

In sub-step (iv) of step S03, the exposed regions 3b of the fin structures 3 are recessed by a suitable etching process, for example, but not limited to, dry etching, wet etching, other suitable etching processes, or combinations thereof, so as to form a plurality of source/drain trenches 43 that are spaced apart from one another in the Y direction. One of the source/drain trenches 43 is shown in FIG. 4. After sub-step (iv) of step S03, the fin structures 3 are formed into a plurality of stack portions 31. Each of the stack portions 31 includes a corresponding one of a plurality of lowermost sacrificial features 241 (formed from the lowermost sacrificial layer portion 221 (see FIG. 3)), a corresponding one of a plurality of lowermost channel features 231 (formed from the lowermost channel layer portion 211 (see FIG. 3)), a corresponding one of a plurality of first intermediate sacrificial features 2431 (formed from the first intermediate sacrificial layer portion 2231 (see FIG. 3)), a corresponding one of a plurality of first intermediate channel features 2331 (formed from the first intermediate channel layer portion 2131 (see FIG. 3)), a corresponding one of a plurality of second intermediate sacrificial features 2432 (formed from the second intermediate sacrificial layer portion 2232 (see FIG. 3)), a corresponding one of a plurality of second intermediate channel features 2332 (formed from the second intermediate channel layer portion 2132 (see FIG. 3)), a corresponding one of a plurality of uppermost sacrificial features 242 (formed from the uppermost sacrificial layer portion 222 (see FIG. 3)), and a corresponding one of a plurality of uppermost channel features 232 (formed from the uppermost channel layer portion 212 (see FIG. 3)).

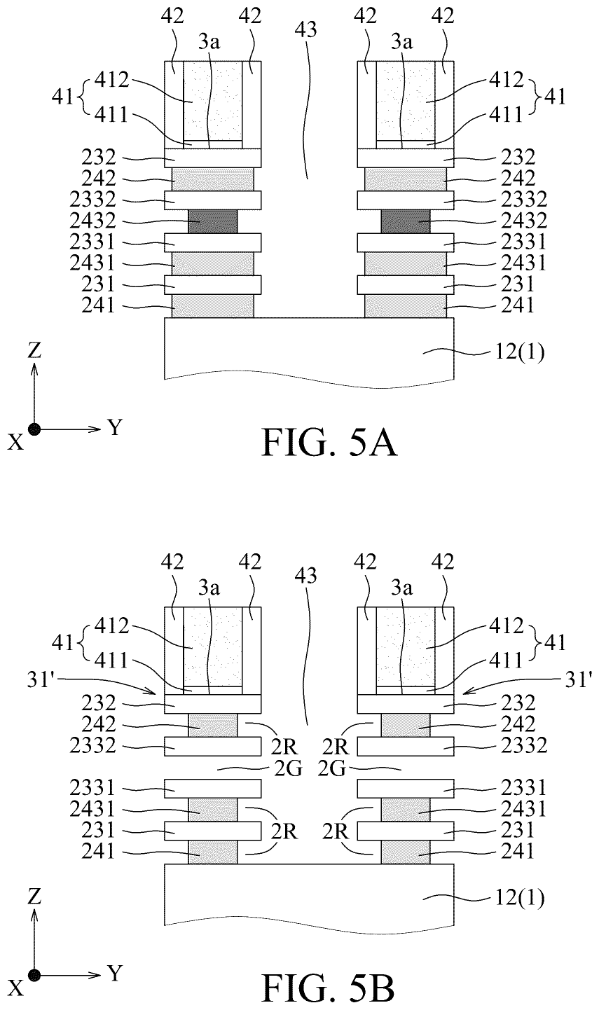

Referring to FIG. 1 and the example illustrated in FIGS. 5A and 5B, the method 100A then proceeds to step S04, where the lowermost sacrificial features 241, the uppermost sacrificial features 242, the first intermediate sacrificial features 2431, and the second intermediate sacrificial features 2432 are laterally recessed so as to form a plurality of lateral recesses 2R and a plurality of gaps 2G. Step S04 may be performed by an isotropic etching process, for example, but not limited to, a wet etching process or other suitable etching processes. In this step, side portions of each of the lowermost sacrificial features 241, the uppermost sacrificial features 242, the first intermediate sacrificial features 2431, and the second intermediate sacrificial features 2432 are gradually removed (see FIG. 5A) until the second intermediate sacrificial features 2432 is completely removed (see FIG. 5B). It is noted that introduction of the n-type dopant may cause an activation energy of the second intermediate sacrificial features 2432 to decrease with respect to that of the lowermost sacrificial features 241, the uppermost sacrificial features 242 and the first intermediate sacrificial features 2431, which are not introduced with the n-type dopant, permitting the etching selectivity (or an etching rate) of the second intermediate sacrificial features 2432 to be greater than that of each of the lowermost sacrificial features 241, the uppermost sacrificial features 242, and the first intermediate sacrificial features 2431, so that the second intermediate sacrificial features 2432 are completely removed while the lowermost sacrificial features 241, the uppermost sacrificial features 242 and the first intermediate sacrificial features 2431 are partially removed (removal of the side portions). After this step, the stack portions 31 are formed into a plurality of recessed stack portions 31′.

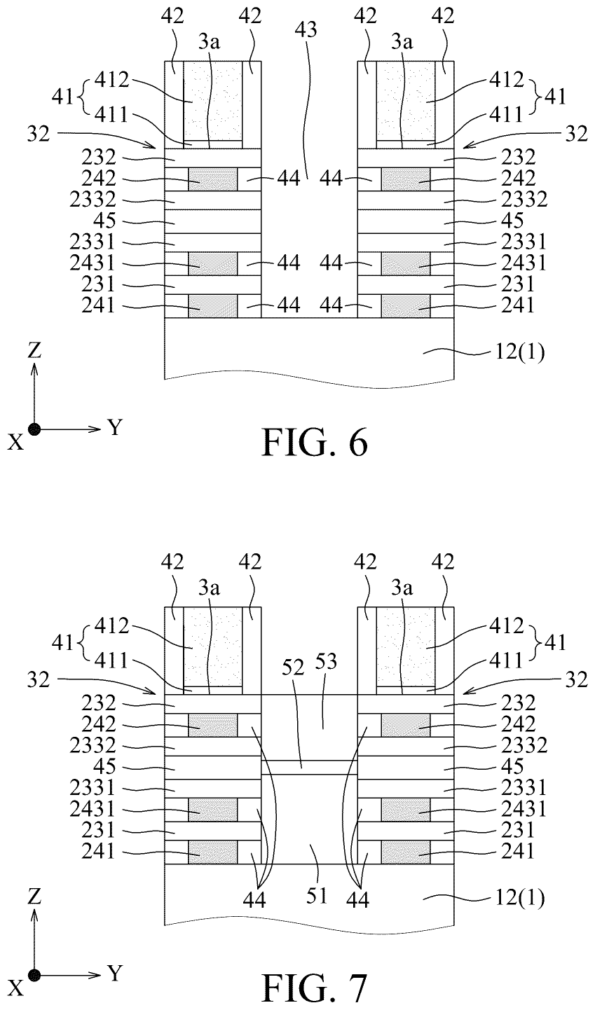

Referring to FIG. 1 and the example illustrated in FIG. 6, the method 100A then proceeds to step S05, where a plurality of inner spacers 44 and a plurality of intermediate isolation features 45 are formed. The inner spacers 44 are formed to respectively fill the lateral recesses 2R (see FIG. 5B) and the intermediate isolation features 45 are formed to respectively fill the gaps 2G (see FIG. 5B). Step S05 may include sub-steps (i) and (ii). Sub-step (i) of step S05 may include depositing a dielectric material (not shown) for forming the inner spacers 44 and the intermediate isolation features 45 on the structure shown in FIG. 5B so as to fill the lateral recesses 2R and the gaps 2G by a suitable deposition process (for example, but not limited, CVD, ALD, or other suitable deposition processes), and sub-step (ii) of step S05 may include removing an excess portion of the dielectric material for forming the inner spacers 44 and the intermediate isolation features 45 by a suitable etching process (for example, but not limited to, an anisotropic etching process or other suitable etching processes), so as to obtain the inner spacers 44 and the intermediate isolation features 45. The dielectric material for forming the inner spacers 44 and the intermediate isolation features 45 may include, for example, but not limited to, silicon oxide, silicon nitride, silicon oxynitride, silicon carbon nitride, silicon oxycarbonitride, silicon oxycarbide, silicon carbide, aluminum oxide, hafnium oxide, zirconium oxide, or combinations thereof. Other suitable materials for forming the inner spacers 44 and the intermediate isolation features 45 are within the contemplated scope of the present disclosure. After this step, the recessed stack portions 31′ are formed into a plurality of stack units 32, respectively.

Referring to FIG. 1 and the example illustrated in FIG. 7, the method 100A then proceeds to step S06, where a lower source/drain portion 51, a middle isolation feature 52, and an upper source/drain portion 53 are sequentially formed in each of the source/drain trenches 43 (i.e., a number of each of the lower source/drain portion 51, the middle isolation feature 52, and the upper source/drain portion 53 is plural). Step S06 may include sub-steps (i) to (iii).

In sub-step (i) of step S06, the lower source/drain portion 51 is formed in each of the source/drain trenches 43 by a suitable epitaxial growth process, for example, but not limited to, MBE, an epitaxial deposition/partial etch process (e.g., a cyclic deposition-etch (CDE) process and/or a SEG process), or other suitable epitaxial growth processes. In some embodiments, the lower source/drain portion 51 may have a p-type conductivity, and may include single crystalline silicon, polycrystalline silicon, single crystalline silicon germanium, polycrystalline silicon germanium, or other suitable materials doped with the p-type dopants (as described in step S01) so as to function as a source/drain of a p-type field-effect transistor (p-FET). In some alternative embodiments, the lower source/drain portion 51 may have an n-type conductivity, and may include single crystalline silicon, polycrystalline silicon, or other suitable materials doped with the n-type dopants (as described in step S01) so as to function as a source/drain of an n-type FET (n-FET).

In sub-step (ii) of step S06, the middle isolation feature 52 is formed to cover the lower source/drain portion 51 in the source/drain trench 43. The sub-step (ii) of step S06 may include (a) depositing an isolation material on the previously obtained structure to fill the source/drain trench 43 by a suitable deposition process, for example, but not limited to, CVD, ALD, or other suitable deposition processes, and (b) performing a photolithography process (as described in step S02) to remove an excess portion of the isolation material, so as to obtain the middle isolation feature 52. The isolation material for forming the middle isolation feature 52 may include, for example, but not limited to, silicon oxide, silicon nitride, silicon oxynitride, silicon carbonitride, silicon oxycarbide, silicon oxycarbonitride, silicon carbide, or combinations thereof. Other suitable materials for forming the middle isolation feature 52 are within the contemplated scope of the present disclosure. In some embodiments, each of the middle isolation features 52 is disposed between and connected to two adjacent ones of the intermediate isolation features 45.

In sub-step (iii) of step S06, the upper source/drain portion 53 is formed in the source/drain trench 43 and on the middle isolation feature 52 opposite to the lower source/drain portion 51. The material and process for forming the upper source/drain portion 53 may be the same as or similar to those for forming the lower source/drain portion 51, and thus details thereof are omitted for the sake of brevity. The upper source/drain portion 53 may have a conductivity type which is the same as or different from that of the lower source/drain portion 51.

Referring to FIG. 1 and the example illustrated in FIG. 8, the method 100A then proceeds to step S07, where a replacement gate process is performed, thereby obtaining the semiconductor device 200A. Step S07 may include sub-steps (i) and (ii).

In sub-step (i) of step S07, the dummy poly gates 41 (see FIG. 7), the uppermost sacrificial features 242, the first intermediate sacrificial features 2431, and the lowermost sacrificial features 241 are removed using one or more suitable etching processes to form a plurality of cavities (not shown). Afterwards, as shown in FIG. 8, in sub-step (ii) of step S07, materials for forming a gate dielectric 461 and a gate electrode 462 are sequentially formed in the cavities using one or more suitable deposition processes (e.g., CVD, ALD, etc.), followed by performing a planarization process (e.g., chemical mechanical polishing (CMP), or other suitable planarization processes) to remove an excess portion of each of the abovementioned materials, thereby obtaining a plurality of gate features 46, each of which includes the gate dielectric 461 and the gate electrode 462.

The gate dielectric 461 is disposed around a corresponding one of the uppermost channel features 232, a corresponding one of the second intermediate channel features 2332, a corresponding one of the first intermediate channel features 2331, and a corresponding one of the lowermost channel features 231. The gate electrode 462 is disposed on the gate dielectric 461 such that each of the corresponding one of the uppermost channel features 232, the corresponding one of the second intermediate channel features 2332, the corresponding one of the first intermediate channel features 2331, and the corresponding one of the lowermost channel features 231 is separated from the gate electrode 462 by the gate dielectric 461.

In some embodiments, the gate dielectric 461 may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. Other suitable dielectric materials for the gate dielectric 461 are within the contemplated scope of the present disclosure. In some embodiments, the gate electrode 462 may be configured as a multi-layered structure including at least one work function metal which is provided for adjusting threshold voltage of an n-FET or a p-FET, an electrically conductive material having a low resistance which is provided for reducing electrical resistance of the gate electrode 462, or combinations thereof. Other suitable materials for the gate electrode 462 are within the contemplated scope of the present disclosure. In some embodiments, the work function metal of the gate electrode 462 for forming an n-FET may be different from that for forming a p-FET so as to permit the n-FET and the p-FET to have different threshold voltages. In some embodiments, the gate electrode 462 may include a metallic material (e.g., tungsten, titanium, tantalum, aluminum, or ruthenium), metal-containing nitrides (e.g., titanium nitride or tantalum nitride), metal-containing silicides (e.g., nickel silicide), metal-containing carbides (e.g., tantalum carbide), or combinations thereof. Other suitable materials for the gate electrode 462 are within the contemplated scope of the present disclosure.

After step S07, the semiconductor device 200A is obtained. In some embodiments, when the conductivity type of the lower source/drain portion 51 is opposite to that of the upper source/drain portion 53, the lower source/drain portion 51 and the upper source/drain portion 53 cooperatively form a CFET structure. For example, the lower source/drain portion 51 has a p-type conductivity and functions as a p-FET, while the upper source/drain portion 53 has an n-type conductivity and functions as an n-FET, and vice versa.

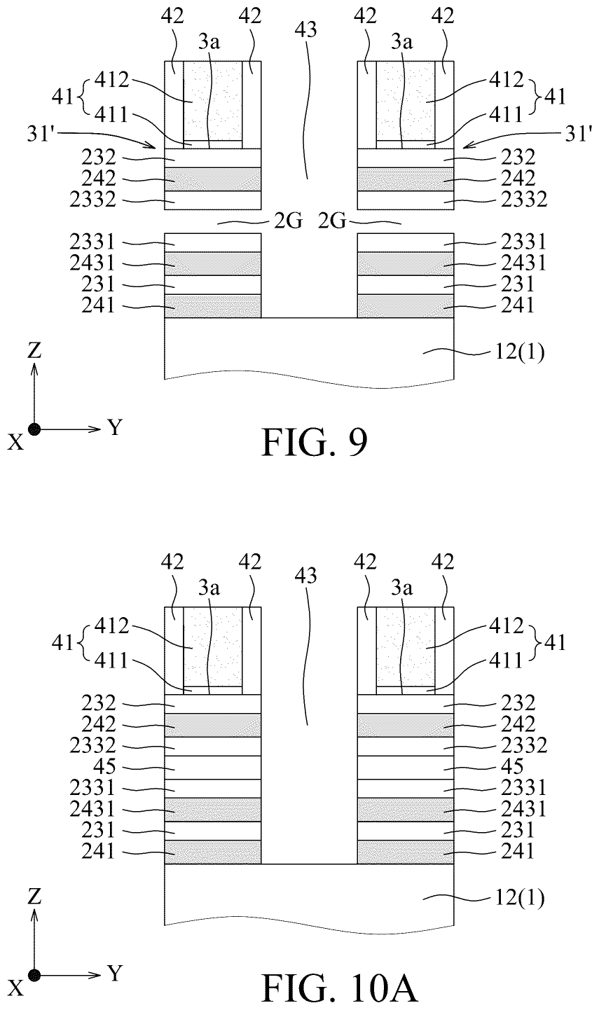

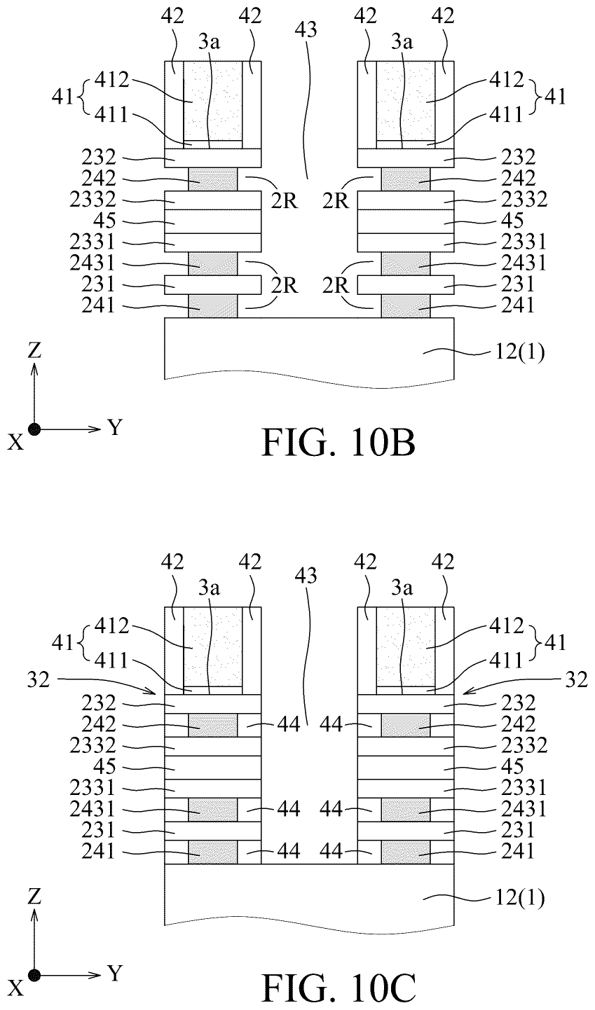

Referring to the examples illustrated in FIGS. 9 to 10C, in some embodiments, steps S04 and S05 of the method 100A may be performed as follows.

Referring to FIG. 9, in step S04, the side portions of each of the lowermost sacrificial features 241 (formed from the lowermost sacrificial layer 221′ shown in FIG. 2A or 2B), the uppermost sacrificial features 242 (formed from the uppermost sacrificial layer 222′ shown in FIG. 2A or 2B), and the first intermediate sacrificial features 2431 (formed from the first intermediate sacrificial layer 2231′ shown in FIG. 2A or 2B) are intact, and the second intermediate sacrificial features 2432 are completely removed, so as to form the gaps 2G. Formation of the gaps 2G may result from the etching selectivity of the second intermediate sacrificial layer 2232′ (see FIG. 2A or 2B) with respect to each of the lowermost sacrificial layer 221′, the uppermost sacrificial layer 222′ and the first intermediate sacrificial layer 2231′ being greater than about 50.

Referring to FIGS. 10A to 10C, in step S05, the intermediate isolation features 45 are formed, followed by sequentially performing an isotropic etching process and forming the inner spacers 44. Step S05 may include sub-steps (i) to (iii).

In sub-step (i) of step S05, as shown in FIG. 10A, the intermediate isolation features 45 are formed to respectively fill the gaps 2G of the structure shown in FIG. 9. Sub-sep (i) of step S05 may be performed by a suitable deposition process (for example, but not limited to, CVD, ALD, or other suitable deposition processes).

In sub-step (ii) of step S05, as shown in FIG. 10B, the isotropic etching process is performed to laterally recess the lowermost sacrificial features 241, the uppermost sacrificial features 242, and the first intermediate sacrificial features 2431. Sub-step (ii) of step S05 is similar to step S04 of the method 100A described above with reference to FIGS. 5A and 5B, and thus details thereof are omitted for the sake of brevity. After sub-step (ii) of step S05, the side portions of each of the lowermost sacrificial features 241, the uppermost sacrificial features 242, and the first intermediate sacrificial features 2431 are removed, so as to form the lateral recesses 2R.

In sub-step (iii) of step S05, as shown in FIG. 10C, the inner spacers 44 are formed to respectively fill the lateral recesses 2R (see FIG. 10B). Sub-step (iii) of step S05 is similar to step S05 of the method 100A described above with reference to FIG. 6, and thus details thereof are omitted for the sake of brevity. In some embodiments, a material for forming the inner spacers 44 is different from that for forming the intermediate isolation features 45.

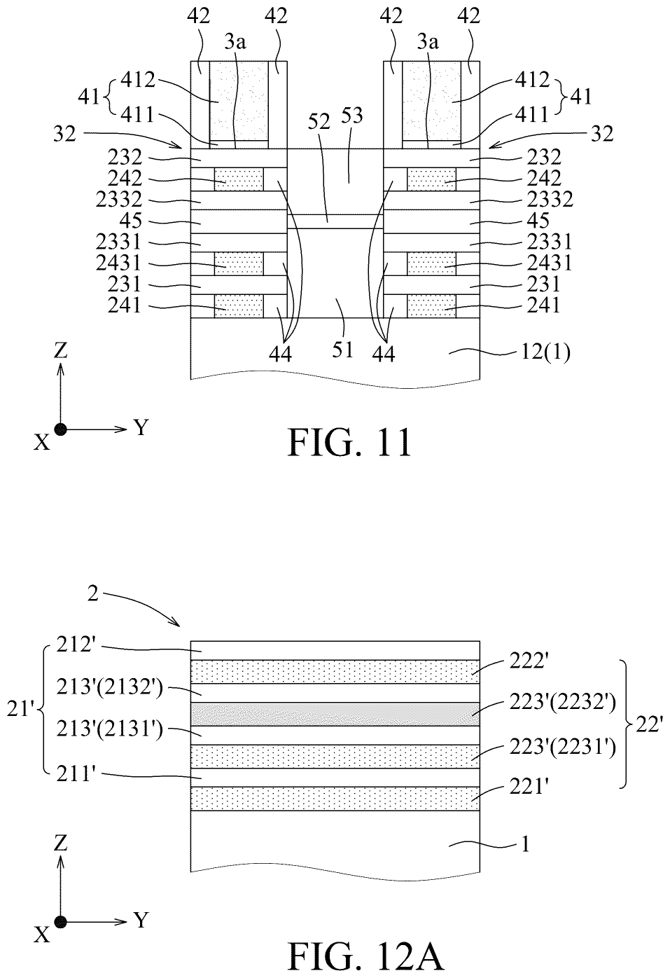

FIG. 11 illustrates a schematic view of a structure in an intermediate stage of the method 100A in accordance with some embodiments. The structure shown in FIG. 11 is similar to the structure shown in FIG. 7 except that, each of the lowermost sacrificial features 241, the uppermost sacrificial features 242, and the first intermediate sacrificial features 2431 is doped with the p-type dopant, the impurity, or a combination thereof. The structure shown in FIG. 11 may be formed as follows.

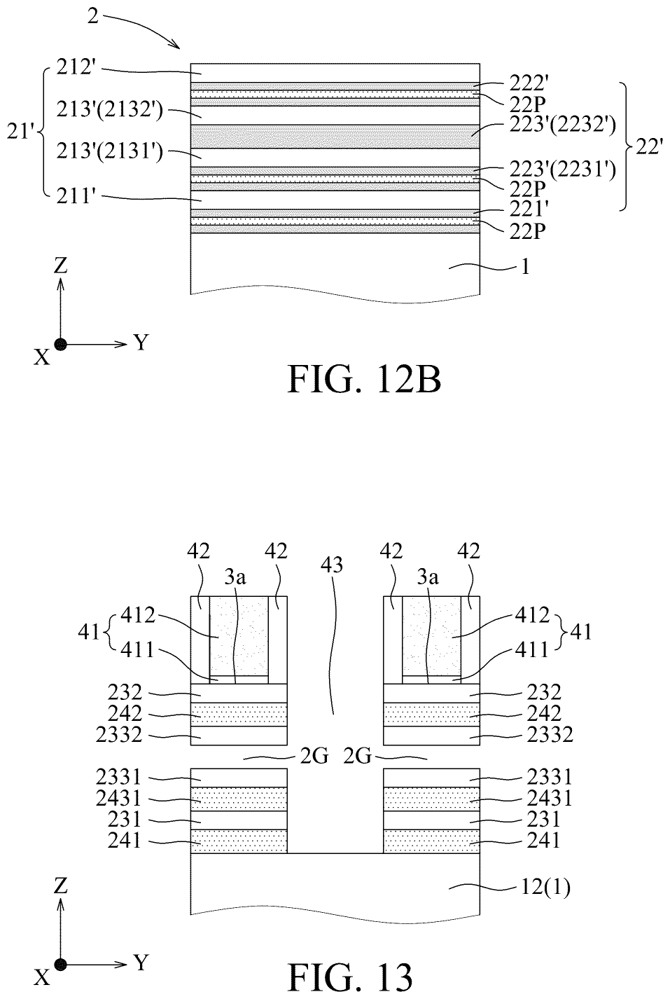

Referring to the examples illustrated in FIGS. 12A and 12B, in step S01 of the method 100A, each of the lowermost sacrificial layer 221′, the uppermost sacrificial layer 222′, and the first intermediate sacrificial layer 2231′ is doped with the p-type dopant, the impurity, or a combination thereof, while the second intermediate sacrificial layer 2232′ is undoped. In this case, the p-type dopant, the impurity, or a combination thereof is distributed in each of the lowermost sacrificial layer 221′, the uppermost sacrificial layer 222′, and the first intermediate sacrificial layer 2231′. An introduction of the p-type dopant or the impurity may cause an activation energy of each of the lowermost sacrificial layer 221′, the uppermost sacrificial layer 222′, and the first intermediate sacrificial layer 2231′ to increase with respect to the second intermediate sacrificial layer 2232′, so that the etching selectivity (or the etching rate) of the second intermediate sacrificial layer 2232′ is greater than that of each of the lowermost sacrificial layer 221′, the uppermost sacrificial layer 222′, and the first intermediate sacrificial layer 2231′. In some embodiments, as shown in FIG. 12A, each of the lowermost sacrificial layer 221′, the uppermost sacrificial layer 222′, and the first intermediate sacrificial layer 2231′ is fully doped with the p-type dopant, the impurity, or a combination thereof. In some alternative embodiments, as shown in FIG. 12B, the p-type dopant, the impurity, or a combination thereof is formed as a p-type sacrificial sublayer 22P in each of the lowermost sacrificial layer 221′, the uppermost sacrificial layer 222′, and the first intermediate sacrificial layer 2231′.

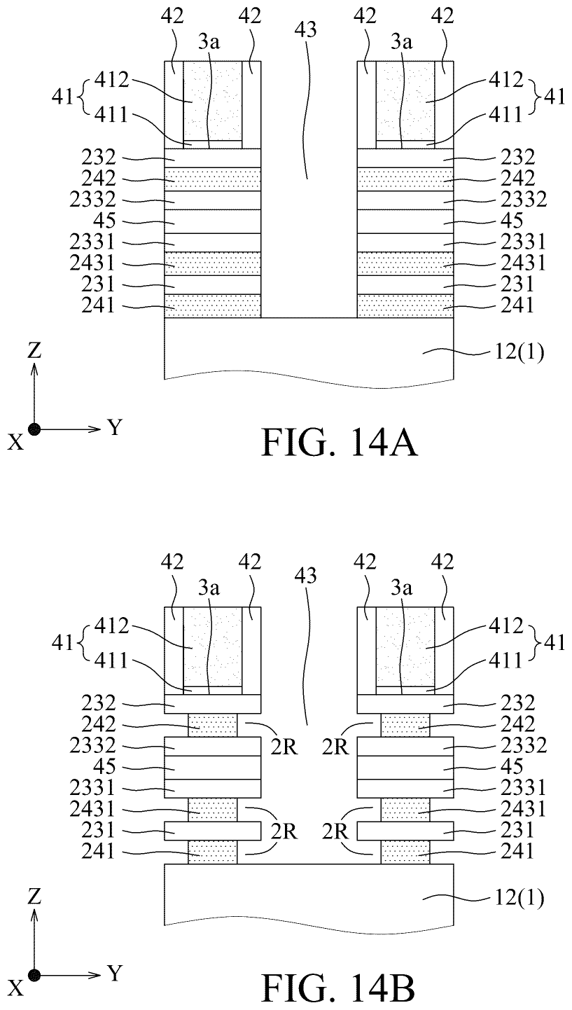

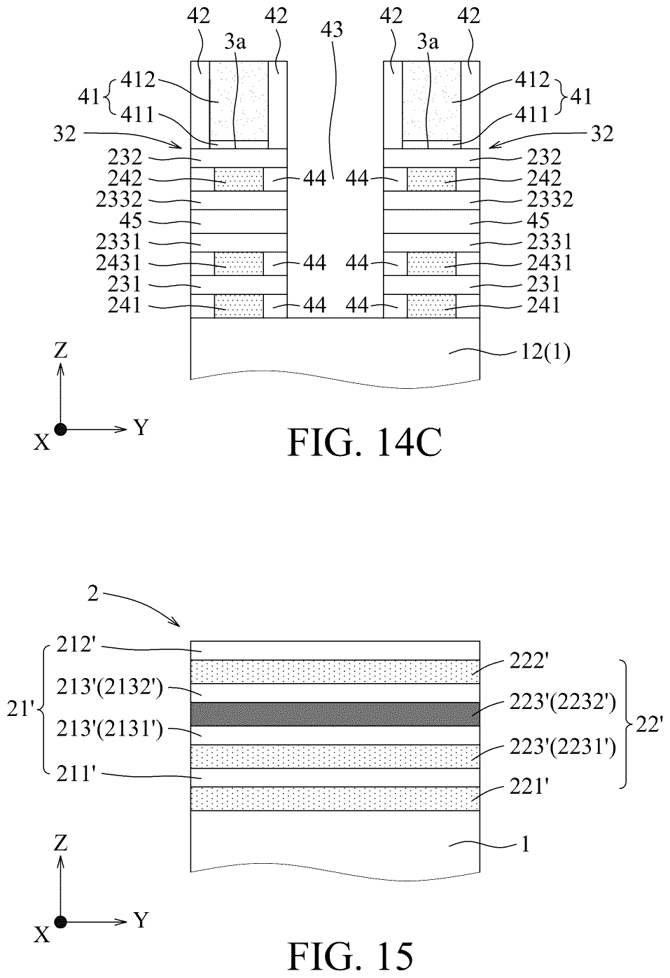

In the examples illustrated in FIGS. 12A, and 13 to 14C, when the etching selectivity of the second intermediate sacrificial layer 2232′ with respect to each of the lowermost sacrificial layer 221′, the uppermost sacrificial layer 222′ and the first intermediate sacrificial layer 2231′ is greater than about 50 (see FIG. 12A), steps S04 and S05 of the method 100A (see FIGS. 13 to 14C) are similar to steps S04 and S05 of the method 100A described above with reference to FIGS. 9 to 10C, and thus details thereof are omitted for the sake of brevity.

After steps S04 and S05, the structure shown in FIG. 14C is subjected to step S06 of the method 100A described above with reference to FIG. 7, thereby obtaining the structure shown in FIG. 11. The structure shown in FIG. 11 is then subjected to step S07 of the method 100A described above with reference to FIG. 8, thereby obtaining the semiconductor device 200A.

In some embodiments, the structure shown in FIG. 7 or the structure shown in FIG. 11 may be obtained by modifying a doping configuration of the second set of layers 22′ of the nanosheet stack 2 in step S01 of the method 100A, which is described as follows.

Referring to FIGS. 15 to 18, each of the lowermost sacrificial layer 221′, the uppermost sacrificial layer 222′, and the first intermediate sacrificial layer 2231′ is doped with the p-type dopant, while the second intermediate sacrificial layer 2232′ is doped with the n-type dopant.

As shown in FIG. 15, in some embodiments, the p-type dopant is uniformly distributed in each of the lowermost sacrificial layer 221′, the uppermost sacrificial layer 222′, and the first intermediate sacrificial layer 2231′, while the n-type dopant is uniformly distributed in the second intermediate sacrificial layer 2232′.

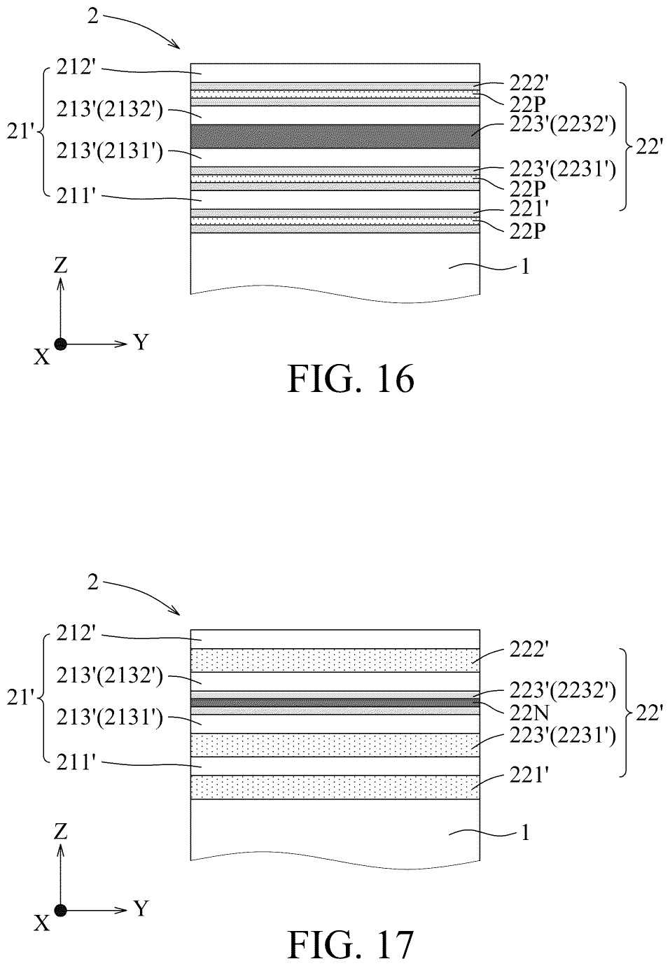

As shown in FIG. 16, in some embodiments, the p-type dopant, the impurity, or a combination thereof is formed as a p-type sacrificial sublayer 22P in each of the lowermost sacrificial layer 221′, the uppermost sacrificial layer 222′, and the first intermediate sacrificial layer 2231′, while the n-type dopant is uniformly distributed in the second intermediate sacrificial layer 2232′. In some embodiments, the p-type sacrificial sublayer 22P may be located in the middle of each of the lowermost sacrificial layer 221′, the uppermost sacrificial layer 222′, and the first intermediate sacrificial layer 2231′. Other locations for the p-type sacrificial sublayer 22P in each of the lowermost sacrificial layer 221′, the uppermost sacrificial layer 222′, and the first intermediate sacrificial layer 2231′ are within the contemplated scope of the present disclosure.

As shown in FIG. 17, in some embodiments, the p-type dopant, the impurity, or a combination thereof is uniformly distributed in each of the lowermost sacrificial layer 221′, the uppermost sacrificial layer 222′, and the first intermediate sacrificial layer 2231′, while the n-type dopant is formed as an n-type sacrificial sublayer 22N in the second intermediate sacrificial layer 2232′. In some embodiments, the n-type sacrificial sublayer 22N may be located in the middle of the second intermediate sacrificial layer 2232′. Other locations for the n-type sacrificial sublayer 22N in the second intermediate sacrificial layer 2232′ are within the contemplated scope of the present disclosure.

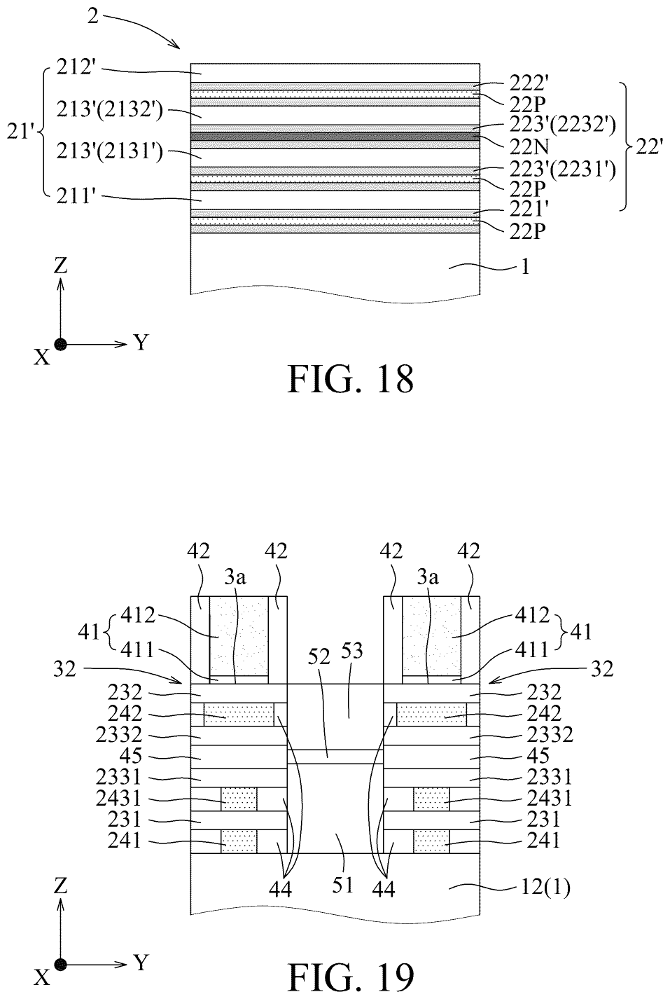

As shown in FIG. 18, in some embodiments, the p-type dopant, or the impurity, or a combination thereof is formed as the p-type sacrificial sublayer 22P in each of the lowermost sacrificial layer 221′, the uppermost sacrificial layer 222′, and the first intermediate sacrificial layer 2231′, while the n-type dopant is formed as the n-type sacrificial sublayer 22N in the second intermediate sacrificial layer 2232′.

FIG. 19 illustrates a schematic view of a structure in an intermediate stage of the method 100A in accordance with some embodiments. The structure shown in FIG. 19 is similar to the structure shown in FIG. 7 except that, in each of the stack units 32 of the structure shown in FIG. 19, each of the lowermost sacrificial feature 241, the uppermost sacrificial feature 242, and the first intermediate sacrificial feature 2431 is doped with the p-type dopant, the impurity, or a combination thereof, and the uppermost sacrificial feature 242 has a width larger than that of each of the lowermost sacrificial feature 241 and the first intermediate sacrificial feature 2431. The structure shown in FIG. 19 may be made by the method 100A in which steps S01, S04 and S05 are performed as follows.

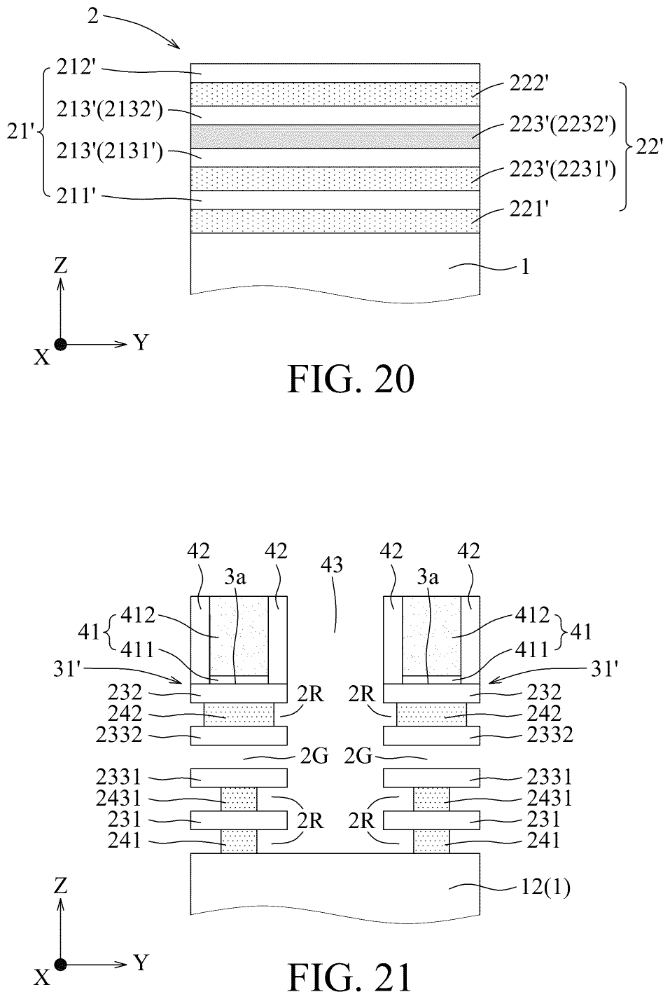

Referring to the example illustrated in FIG. 20, in step S01, each of the lowermost sacrificial layer 221′, the uppermost sacrificial layer 222′, and the first intermediate sacrificial layer 2231′ is doped with the p-type dopant, and a concentration of the p-type dopant in the uppermost sacrificial layer 222′ is higher than that of each of the lowermost sacrificial layer 221′ and the first intermediate sacrificial layer 2231′. In this case, the second intermediate sacrificial layer 2232′ is undoped.

Referring to the example illustrated in FIG. 21, in step S04, the isotropic etching process is performed to obtain the recessed stack portions 31′. In each of the recessed stack portions 31′, a portion of the uppermost sacrificial feature 242 (formed from the uppermost sacrificial layer 222′) which is laterally recessed is less than that of each of the lowermost sacrificial feature 241 (formed from the lowermost sacrificial layer 221′) and the first intermediate sacrificial feature 2431 (formed from the first intermediate sacrificial layer 2231′) which is laterally recessed. It is noted that, in step S04, in comparison to the lowermost sacrificial feature 241 and the first intermediate sacrificial feature 2431, the uppermost sacrificial feature 242 of the each of the recessed stack portions 31′ is more resistant to the etching process (i.e., the isotropic etching process) due to the relatively higher concentration of the p-type dopant.

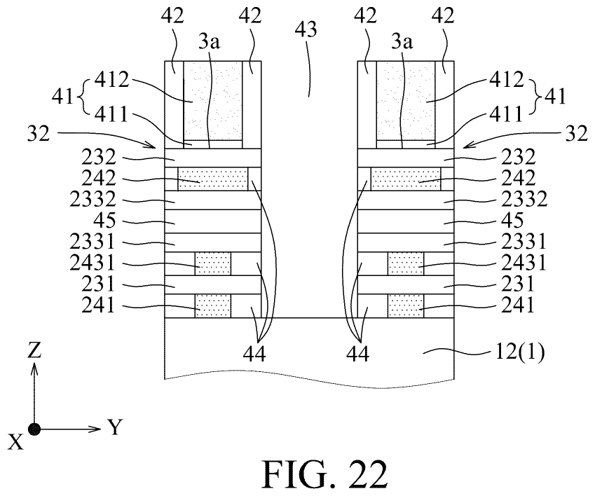

Referring to the example illustrated in FIG. 22, in step S05, the inner spacers 44 and the intermediate isolation features 45 are formed. Each of the inner spacers 44 laterally covering a corresponding one of the uppermost sacrificial features 242 has a thickness in the Y direction, which is smaller than a thickness of each of the inner spacers 44 laterally covering a corresponding one of the lowermost sacrificial features 241, and which is smaller than a thickness of each of the inner spacers 44 laterally covering a corresponding one of the first intermediate sacrificial features 2431.

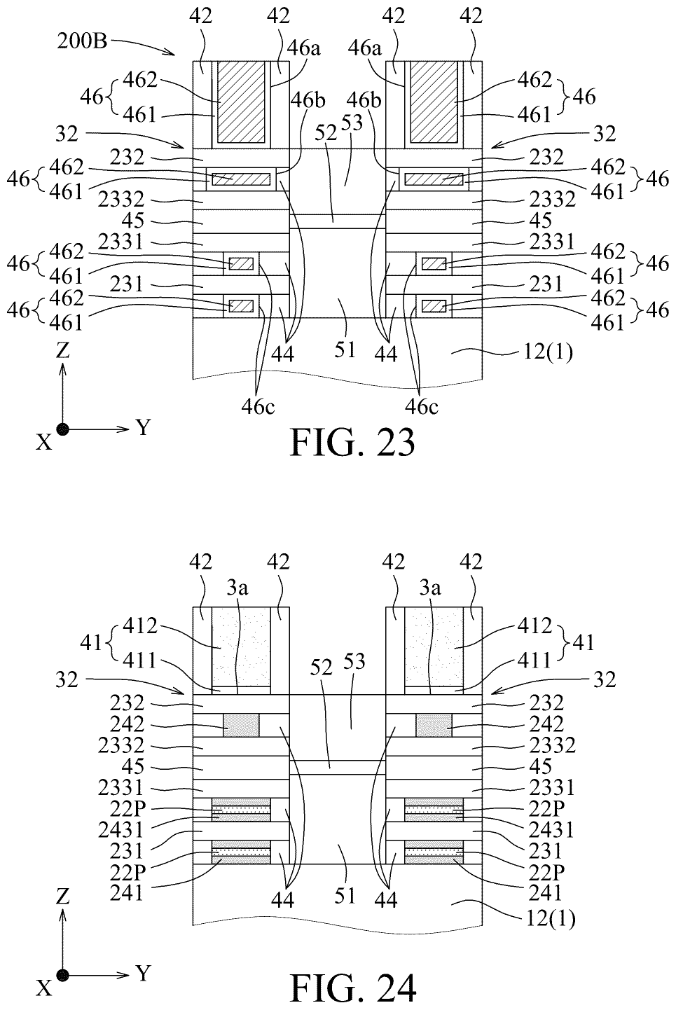

Referring to the example illustrated in FIG. 23, the structure shown in FIG. 19 is subjected to step S07 (i.e., the replacement gate process) described above with reference to FIG. 8 so as to obtain a semiconductor device 200B. In the semiconductor device 200B, each of the gate features 46 includes a first gate portion 46a disposed on a corresponding one of the uppermost channel features 232, at least one second gate portion 46b disposed between the corresponding one of the uppermost channel features 232 and a corresponding one of the intermediate isolation features 45, and at least one third gate portion 46c disposed between the corresponding one of the intermediate isolation features 45 and a corresponding one of the lowermost channel features 231. The at least one second gate portion 46b has a width in the Y direction which is greater than a width of the at least one third gate portion 46c in the Y direction.

FIG. 24 illustrates a schematic view of a structure in an intermediate stage of the method 100A in accordance with some embodiments. The structure shown in FIG. 24 is similar to the structure shown in FIG. 7 except that, in each of the stack units 32 of the structure shown in FIG. 24, the uppermost sacrificial feature 242 has a width in the Y direction which is smaller than that of each of the lowermost sacrificial feature 241 and the first intermediate sacrificial feature 2431. The structure shown in FIG. 24 may be made by the method 100A in which steps S01, S04 and S05 are performed as follows.

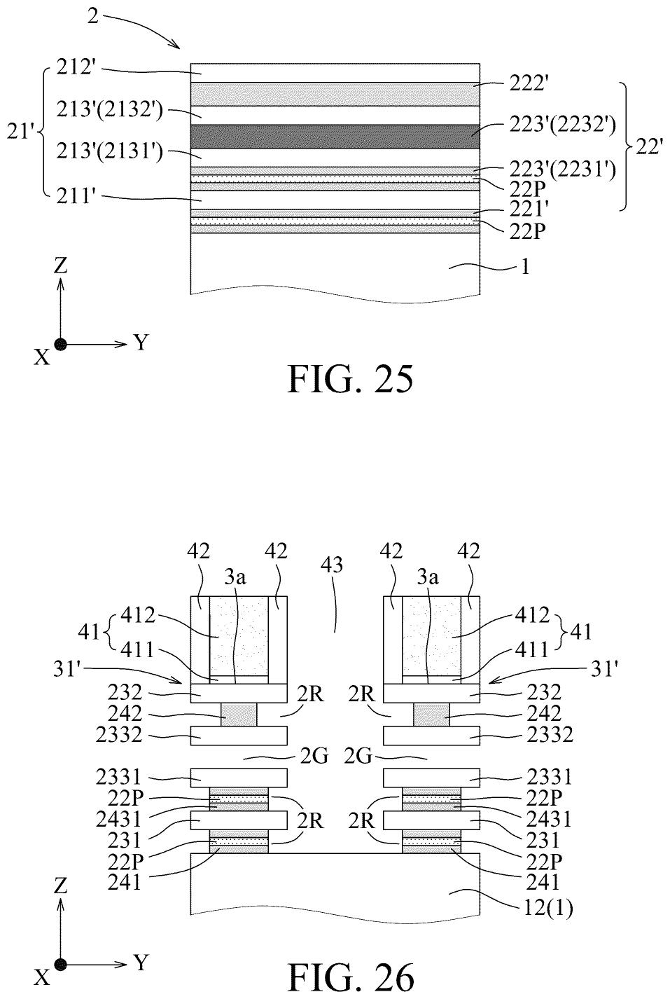

Referring to the example illustrated in FIG. 25, in step S01, each of the lowermost sacrificial layer 221′ and the first intermediate sacrificial layer 2231′ includes the p-type sacrificial sublayer 22P, while the second intermediate sacrificial layer 2232′ is doped with the n-type dopant that is uniformly distributed therein.

Referring to the example illustrate in FIG. 26, after step S04 (i.e., the isotropic etching process) is performed, in each of the recessed stack portions 31′, a portion of the uppermost sacrificial feature 242 (formed from the uppermost sacrificial layer 222′) which is laterally recessed is greater than that of each of the lowermost sacrificial feature 241 (formed from the lowermost sacrificial layer 221′) and the first intermediate sacrificial feature 2431 (formed from the first intermediate sacrificial layer 2231′) which is laterally recessed. It is noted that, in step S04, the lowermost sacrificial feature 241 and the first intermediate sacrificial feature 2431 of each of the recessed stack portions 31′ are more resistant to the etching process (e.g., the isotropic etching process) due to the presence of the p-type sacrificial sublayer 22P, and the uppermost sacrificial feature 242 of each of the recessed stack portions 31′ is vulnerable to the etching process due to the presence of the n-type dopant.

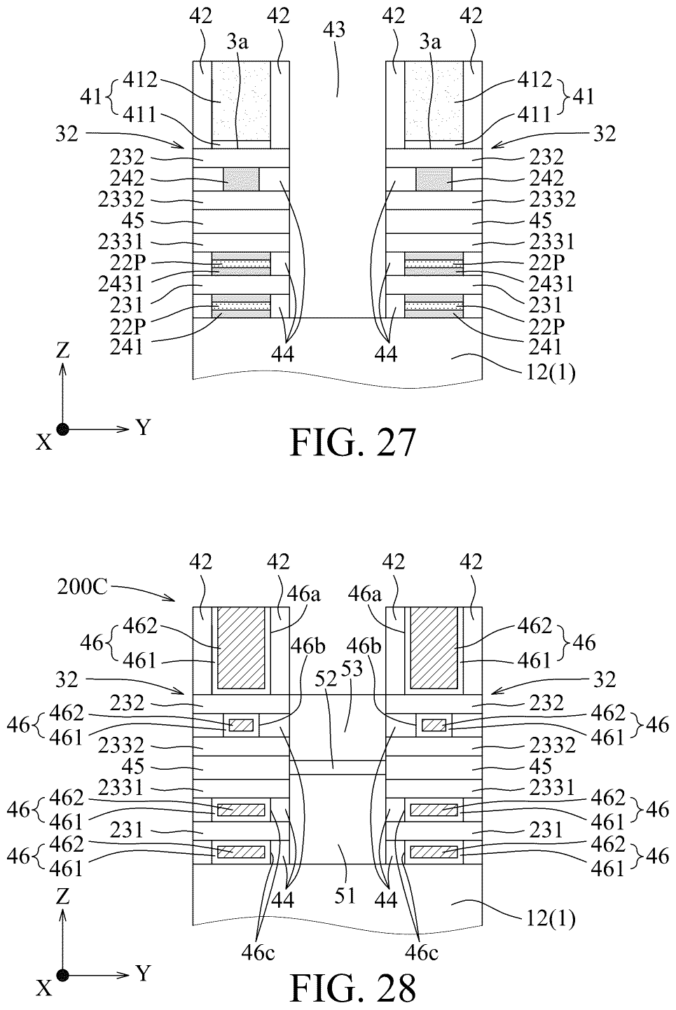

Referring to the example illustrated in FIG. 27, in step S05, the inner spacers 44 and the intermediate isolation features 45 are formed. Each of the inner spacers 44 laterally covering a corresponding one of the uppermost sacrificial features 242 has a thickness in the Y direction, which is greater than a thickness of each of the inner spacers 44 laterally covering a corresponding one of the lowermost sacrificial features 241, and which is greater than a thickness of each of the inner spacers 44 laterally covering a corresponding one of the first intermediate sacrificial features 2431.

Referring to the example illustrated in FIG. 28, the structure shown in FIG. 27 is subjected to step 06 (formation of the lower source/drain portion 51, the middle isolation feature 52, and the upper source/drain portion 53 of the structure shown in FIG. 24) and step S07 (i.e., the replacement gate process) described above with reference to FIGS. 7 and 8 so as to obtain a semiconductor device 200C. In the semiconductor device 200C, the at least one second gate portion 46b has a width in the Y direction which is smaller than a width of the at least one third gate portion 46c in the Y direction.

FIG. 29 illustrates that, when at least one layer (e.g., the uppermost sacrificial layer 222′) in the second set of layers 22′ is doped with a dopant (e.g., boron (B)) in step S01 of the method 100A, the dopant in a sacrificial feature thus formed (e.g., one of the uppermost sacrificial features 242 formed from the uppermost sacrificial layer 222′) may diffuse into an adjacent one of channel features (e.g., one of the uppermost channel features 232 formed from the uppermost channel layer 212′) in a subsequent thermal process (e.g., an annealing process), which is conducive to improving device performance of a semiconductor device (e.g., the semiconductor device 200A).

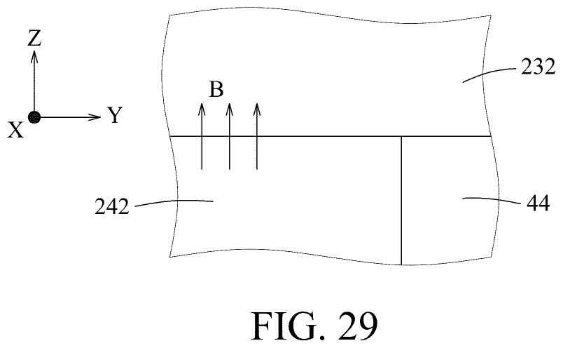

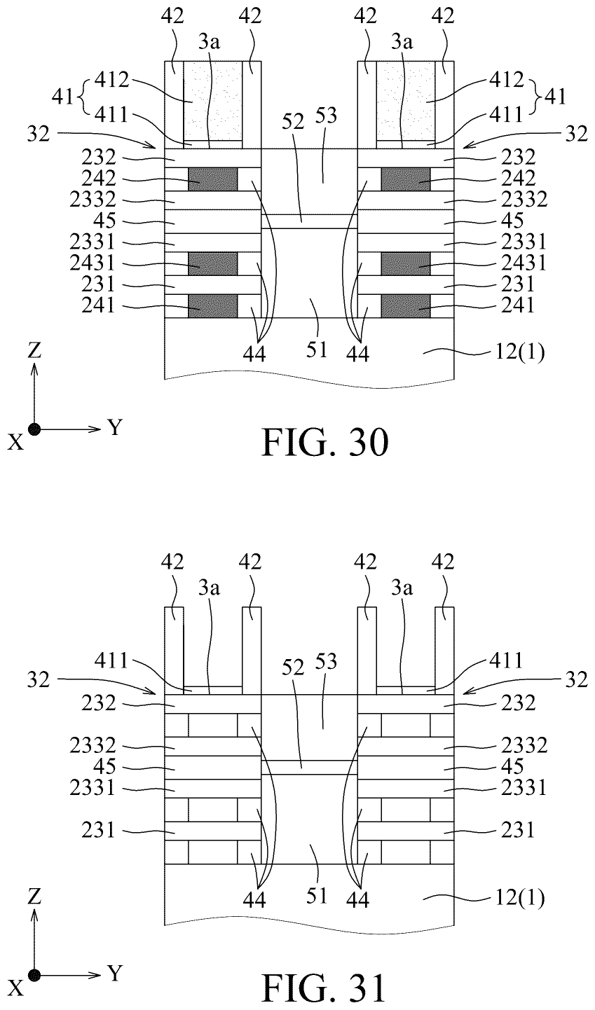

FIG. 30 illustrates a schematic view of a structure in an intermediate stage of the method 100A in accordance with some embodiments. In the structure shown in FIG. 30, each of the lowermost sacrificial features 241, the uppermost sacrificial features 242, and the first intermediate sacrificial features 2431 is doped with the n-type dopant. The second intermediate sacrificial features 2432 (not shown in FIG. 30) described above are replaced with the intermediate isolation features 45, respectively. The structure shown in FIG. 30 may be made using the method 100A in which step S01 is performed as follows.

Each of the lowermost sacrificial layer 221′, the uppermost sacrificial layer 222′, the first intermediate sacrificial layer 2231′, and the second intermediate sacrificial layer 2232′ is doped with the n-type dopant, and a germanium concentration in the second intermediate sacrificial layer 2232′ is higher than that of each of the lowermost sacrificial layer 221′, the uppermost sacrificial layer 222′, and the first intermediate sacrificial layer 2231′. In this case, the etching selectivity of the second intermediate sacrificial layer 2232′, which has the germanium concentration that is greater than that of each of the lowermost sacrificial layer 221′, the uppermost sacrificial layer 222′, and the first intermediate sacrificial layer 2231′.

FIG. 31 illustrates a schematic view of a structure which is formed by subjecting the structure shown in FIG. 30 to a subsequent etching process (may be referred to as a sheet formation process). After the subsequent etching process, the lowermost sacrificial features 241, the uppermost sacrificial features 242, the first intermediate sacrificial features 2431, and the dummy gate electrode 412 of each of the dummy poly gates 41 of the structure shown in FIG. 30 are removed. In some embodiments, the etching process may be a dry etching process, a wet etching process, or a combination thereof. In some embodiments, an etchant used in the etching process may include, for example, but not limited to, fluorine (F₂) gas, hydrogen fluoride (HF) gas, nitrogen trifluoride (NF₃) gas, fluoride radical gas, or combinations thereof. In some embodiments, the etching selectivity of each of the lowermost sacrificial features 241, the uppermost sacrificial features 242, and the first intermediate sacrificial features 2431 may be increased by increasing the germanium concentration in each of the lowermost sacrificial layer 221′, the uppermost sacrificial layer 222′, and the first intermediate sacrificial layer 2231′ on the condition that the germanium concentration in each of the lowermost sacrificial layer 221′, the uppermost sacrificial layer 222′, and the first intermediate sacrificial layer 2231′ is lower than that of the second intermediate sacrificial layer 2232′, so that the lowermost sacrificial features 241, the uppermost sacrificial features 242, and the first intermediate sacrificial features 2431 may be removed in a relatively short time period and an exposure time of the structure shown in FIG. 31 is reduced, which is conducive to reducing risk of the lower source/drain portion 51 and the upper source/drain portion 53 being damaged in the etching process, and thus improves the production yield of the semiconductor device of the present disclosure applied in an electrical assembly.

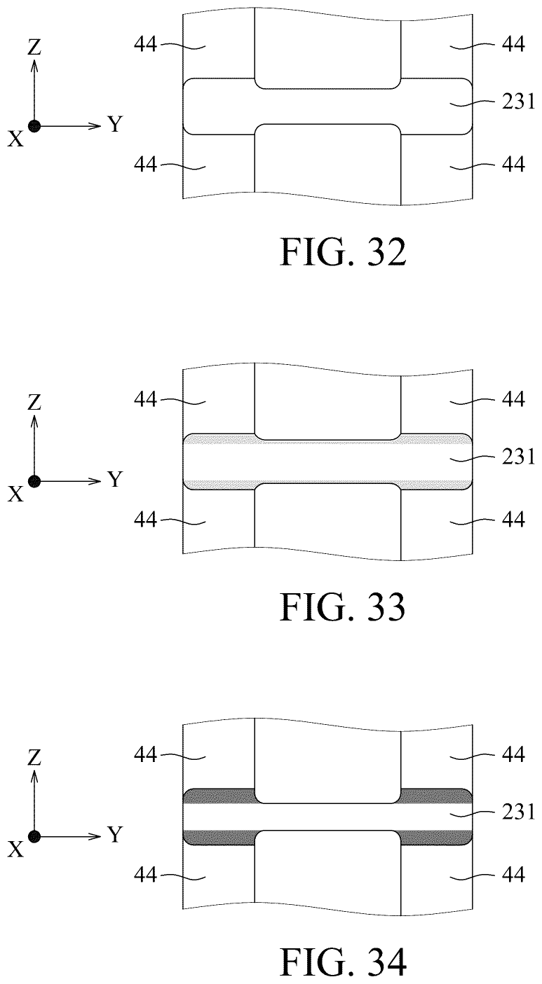

FIG. 32 illustrates one of the lowermost channel features 231 and adjacent inner spacers 44 of a structure formed by subjecting the structure shown in FIG. 7 to the subsequent etching process. As shown in FIG. 32, the lowermost channel feature 231 is partially recessed after the subsequent etching process.

FIG. 33 illustrates one of the lowermost channel features 231 and adjacent inner spacers 44 of a structure formed by subjecting the structure shown in FIG. 11 to the subsequent etching process. Compared with the one of the lowermost channel features 231 shown in FIG. 32, a recessed portion of the one of the lowermost channel features 231 shown in FIG. 33 is relatively smaller. In this case, since each of the lowermost sacrificial features 241 and the first intermediate sacrificial features 2431 is doped with the p-type dopant, the p-type dopant thereof may diffuse into a corresponding one of the lowermost channel features 231 (i.e., the lowermost channel feature 231 shown in FIG. 33) to decrease the etching selectivity or the etching rate of the corresponding one of the lowermost channel features 231 so that the corresponding one of the lowermost channel features 231 is relatively resistant to the subsequent etching process.

FIG. 34 illustrates one of the lowermost channel features 231 and adjacent inner spacers 44 of the structure shown in FIG. 31, which is formed by subjecting the structure shown in FIG. 30 to the subsequent etching process. Compared with the one of the lowermost channel features 231 shown in FIG. 32, a recessed portion of the lowermost channel feature 231 shown in FIG. 34 is relatively larger. In this case, since each of the lowermost sacrificial features 241 and the first intermediate sacrificial features 2431 is doped with the n-type dopant, the n-type dopant thereof may diffuse into a corresponding one of the lowermost channel features 231 (i.e., the lowermost channel feature 231 shown in FIG. 34) to increase the etching selectivity or the etching rate of the corresponding one of the lowermost channel features 231, so that the corresponding one of the lowermost channel features 231 is vulnerable to the subsequent etching process.

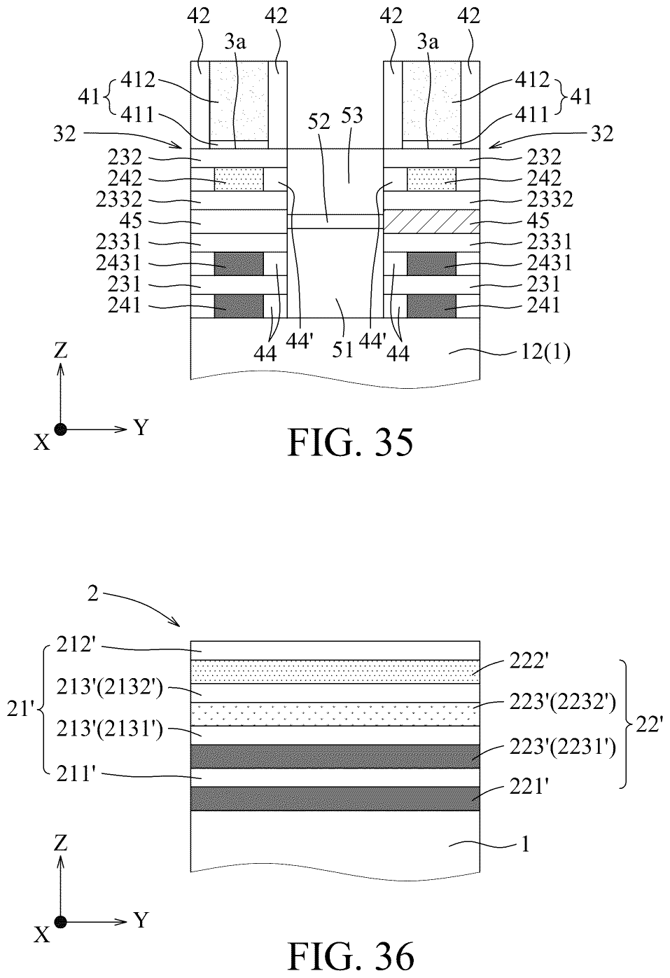

FIG. 35 illustrates a schematic view of a structure in an intermediate stage of the method 100A in accordance with some embodiments. The structure shown in FIG. 35 is similar to the structure shown in FIG. 30 except that, in the structure shown in FIG. 35, each of the uppermost sacrificial features 242 is doped with the p-type dopant. The structure shown in FIG. 35 may be made by the method 100A in which steps S01 to S07 are performed as follows.

Referring to FIG. 36, in step S01, each of the lowermost sacrificial layer 221′, the first intermediate sacrificial layer 2231′ and the second intermediate sacrificial layer 2232′ is fully doped with the n-type dopant, the uppermost sacrificial layer 222′ is fully doped with the p-type dopant, and the germanium concentration of the second intermediate sacrificial layer 2232′ is greater than that of each of the lowermost sacrificial layer 221′, the uppermost sacrificial layer 222′ and the first intermediate sacrificial layer 2231′.

Referring to FIG. 37, steps S02 to S04, which are respectively similar to steps S02 to S04 described above with reference to FIGS. 3 to 5B, are performed. It is noted that the uppermost sacrificial features 242 are intact after step S04.

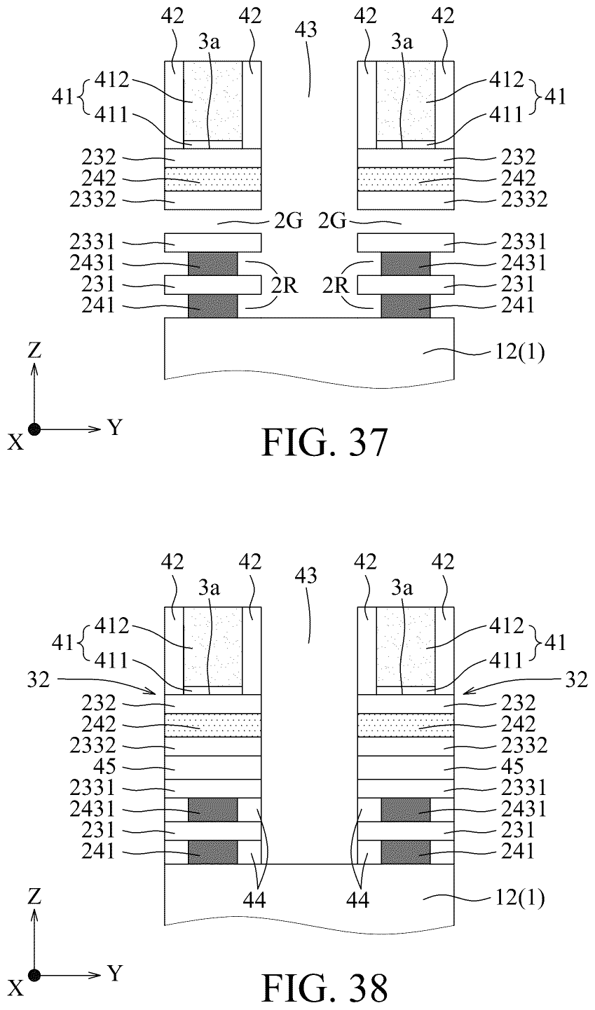

Referring to FIG. 38, step S05 (i.e., formation of the inner spacers 44 and the intermediate isolation features 45) is performed. It is noted that at this stage, no inner spacers are formed to laterally cover the uppermost sacrificial features 242, respectively.

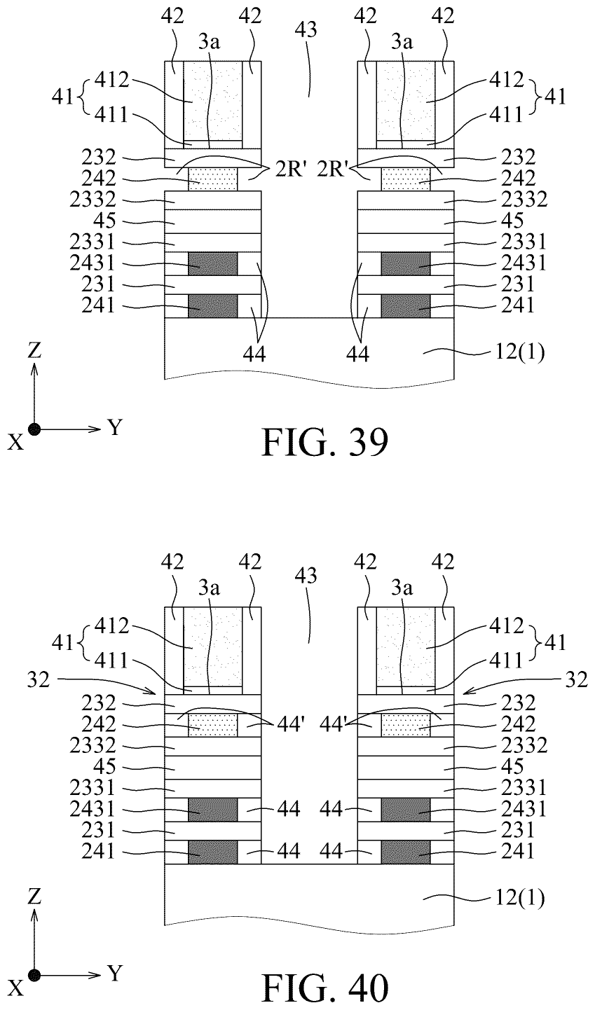

Referring to FIG. 39, the uppermost sacrificial features 242 are laterally recessed so as to form a plurality of lateral recesses 2R′.

Referring to FIG. 40, a plurality of upper inner spacers 44′ are formed. The upper inner spacers 44′ are formed to fill the lateral recesses 2R′ (see FIG. 39), and each pair of the upper inner spacers 44′ laterally covers a corresponding one of the uppermost sacrificial features 242. In some embodiments, the inner spacers 44 and the upper inner spacers 44′ are made of different materials, which can achieve different functions (e.g., resistant to etching process or capable of efficiently isolating two elements).

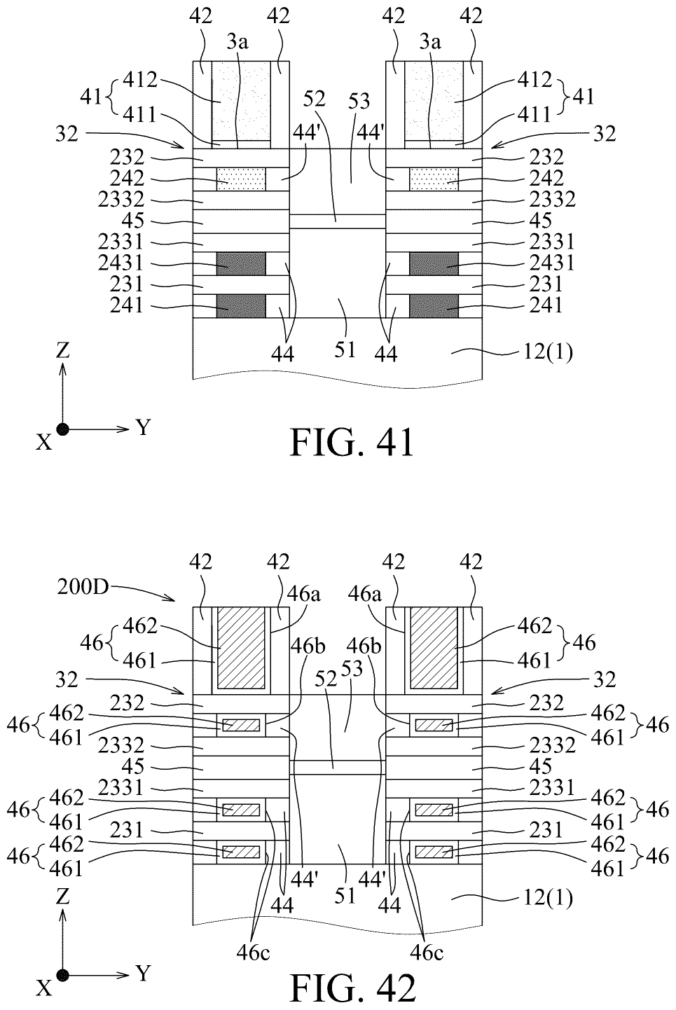

Referring to FIG. 41, step S06 is performed to form the lower source/drain portion 51, the middle isolation feature 52, and the upper source/drain portion 53 sequentially.

FIG. 42 illustrates a semiconductor device 200D obtained after the structure shown in FIG. 41 is performed with the replacement gate process described above with reference to FIG. 8.

In this disclosure, by introducing a dopant or an impurity into at least one sacrificial layer of a nanosheet stack that is used to form a semiconductor device, an etching selectivity of the at least one sacrificial layer with respect to other sacrificial layer(s) may be modified, which is conducive to formation of isolation features and inner spacers in a subsequent process, and to avoid source/drain portions being damaged in a subsequent etching process (e.g., a sheet formation process). Therefore, device performance and production yield of the semiconductor device made by the method of this disclosure may be improved.

In accordance with some embodiments of the present disclosure, a method for manufacturing a semiconductor device includes: forming a plurality of stack portions on a semiconductor substrate in a first direction normal to the semiconductor substrate, the stack portions being spaced apart from each other by a plurality of source/drain trenches which are disposed to alternate with the stack portions in a second direction parallel to the semiconductor substrate and transverse to the first direction, each of the stack portions including a set of channel features and a set of sacrificial features disposed to alternate with the set of the channel features in the first direction, the set of the channel features including a lowermost channel feature, an uppermost channel feature, and at least one intermediate channel feature disposed between the lowermost channel feature and the uppermost channel feature, the set of the sacrificial features including a lowermost sacrificial feature, an uppermost sacrificial feature, and at least one intermediate sacrificial feature disposed between the lowermost sacrificial feature and the uppermost sacrificial feature, the set of the channel features including a first semiconductor material, the set of the sacrificial features including a second semiconductor material different from the first semiconductor material, so as to permit each sacrificial feature of the set of the sacrificial features to have an etching selectivity that is greater than an etching selectivity of each channel feature of the set of the channel features, at least one sacrificial feature of the set of the sacrificial features including an n-type dopant, a p-type dopant, an impurity, or combinations thereof so as to permit one intermediate sacrificial feature of the set of the sacrificial features to have an etching selectivity that is greater than an etching selectivity of the other sacrificial features of the set of the sacrificial features; forming a plurality of dummy poly gates on the stack portions, respectively; removing the one intermediate sacrificial feature to form a gap between the lowermost sacrificial feature and the uppermost sacrificial feature of each of the stack portions; removing two opposite side portions of each of the other sacrificial features of the set of the sacrificial features to form a plurality of recesses, each pair of the recesses being formed at two opposite sides of a corresponding one sacrificial feature of the other sacrificial features of the set of the sacrificial features; forming an intermediate isolation feature to fill the gap; forming a plurality of inner spacers to respectively fill the recesses; forming a plurality of lower source/drain portions in the source/drain trenches, respectively; forming a plurality of middle isolation features to cover the lower source/drain portions in the source/drain trenches, respectively; and forming a plurality of upper source/drain portions to cover the middle isolation features in the source/drain trenches, respectively.

In accordance with some embodiments of the present disclosure, the one intermediate sacrificial feature includes the n-type dopant which includes phosphorus, arsenic, antimony, or combinations thereof.

In accordance with some embodiments of the present disclosure, the n-type dopant is formed as an n-type sacrificial sublayer in the one intermediate sacrificial feature.

In accordance with some embodiments of the present disclosure, each of the other sacrificial features of the set of the sacrificial features includes the p-type dopant which includes boron, aluminum, gallium, indium, or combinations thereof.

In accordance with some embodiments of the present disclosure, the p-type dopant is formed as a p-type sacrificial sublayer in each of the other sacrificial features of the set of the sacrificial features.

In accordance with some embodiments of the present disclosure, the one intermediate sacrificial feature includes the n-type dopant which includes phosphorus, arsenic, antimony, or combinations thereof, and each of the other sacrificial features of the set of the sacrificial features includes the p-type dopant which includes boron, aluminum, gallium, indium, or combinations thereof.

In accordance with some embodiments of the present disclosure, the p-type dopant is formed as a p-type sacrificial sublayer in each of the other sacrificial features of the set of the sacrificial features.

In accordance with some embodiments of the present disclosure, the n-type dopant is formed as an n-type sacrificial sublayer in the one intermediate sacrificial feature.

In accordance with some embodiments of the present disclosure, the gap is formed before formation of the recesses, so that the intermediate isolation feature is formed before formation of the inner spacers.

In accordance with some embodiments of the present disclosure, the inner spacers and the intermediate isolation feature are made of different dielectric materials.

In accordance with some embodiments of the present disclosure, each sacrificial feature of the set of the sacrificial features includes silicon germanium and the n-type dopant which includes boron, aluminum, gallium, indium or combinations thereof. A concentration of germanium in the one intermediate sacrificial feature is greater than a concentration of germanium in each sacrificial feature of the other sacrificial features of the set of the sacrificial features.

In accordance with some embodiments of the present disclosure, the impurity includes carbon, nitrogen, oxygen, or combinations thereof.

In accordance with some embodiments of the present disclosure, a method for manufacturing a semiconductor device includes: forming a plurality of stack portions on a semiconductor substrate in a first direction normal to the semiconductor substrate, the stack portions being spaced apart from each other by a plurality of source/drain trenches which are disposed to alternate with the stack portions in a second direction parallel to the semiconductor substrate and transverse to the first direction, each of the stack portions including a set of channel features and a set of sacrificial features disposed to alternate with the set of the channel features in the first direction, the set of the channel features including a lowermost channel feature, an uppermost channel feature, and at least one intermediate channel feature disposed between the lowermost channel feature and the uppermost channel feature, the set of the sacrificial features including a lowermost sacrificial feature, an uppermost sacrificial feature, and at least one intermediate sacrificial feature disposed between the lowermost sacrificial feature and the uppermost sacrificial feature, the set of the channel features including a first semiconductor material, the set of the sacrificial features including a second semiconductor material different from the first semiconductor material, so as to permit each sacrificial feature of the set of the sacrificial features to have an etching selectivity that is greater than an etching selectivity of each channel feature of the set of the channel features, at least one sacrificial feature of the set of the sacrificial features including an n-type dopant, a p-type dopant, an impurity, or combinations thereof so as to permit one intermediate sacrificial feature of the set of the sacrificial features to have an etching selectivity that is greater than an etching selectivity of the other sacrificial features of the set of the sacrificial features; forming a plurality of dummy poly gates on the stack portions, respectively; removing the one intermediate sacrificial feature to form a gap between the lowermost sacrificial feature and the uppermost sacrificial feature of each of the stack portions; removing two opposite side portions of each of the other sacrificial features of the set of the sacrificial features to form a plurality of recesses, each pair of the recesses being formed at two opposite sides of a corresponding one sacrificial feature of the other sacrificial features of the set of the sacrificial features; forming an intermediate isolation feature to fill the gap; forming a plurality of inner spacers to respectively fill the recesses; forming a plurality of lower source/drain portions in the source/drain trenches, respectively; forming a plurality of middle isolation features to cover the lower source/drain portions in the source/drain trenches, respectively; forming a plurality of upper source/drain portions to cover the middle isolation features in the source/drain trenches, respectively; removing the dummy poly gates and the other sacrificial features of the set of the sacrificial features to form a plurality of cavities; and forming a gate feature in each of the cavities.

In accordance with some embodiments of the present disclosure, the gap and the recesses are formed simultaneously, so that the intermediate isolation feature and the inner spacers are formed simultaneously.

In accordance with some embodiments of the present disclosure, each sacrificial feature of the other sacrificial features of the set of the sacrificial features includes the p-type dopant, the impurity, or a combination thereof. The p-type dopant includes boron, aluminum, gallium, indium, or combinations thereof. The impurity includes carbon, nitrogen, oxygen, or combinations thereof.

In accordance with some embodiments of the present disclosure, each sacrificial feature of the other sacrificial features of the set of the sacrificial features includes the p-type dopant including boron, aluminum, gallium, indium, or combinations thereof, and a concentration of the p-type dopant in the uppermost sacrificial feature of the other sacrificial features of the set of the sacrificial features is higher than a concentration of the p-type dopant in remaining sacrificial features of the other sacrificial features of the set of the sacrificial features, so that one of the inner spacers formed to laterally cover the uppermost sacrificial feature has a thickness that is less than a thickness of each of the inner spacers formed to laterally cover the remaining sacrificial features of the other sacrificial features of the set of the sacrificial features.

In accordance with some embodiments of the present disclosure, the at least one intermediate sacrificial feature includes a first intermediate sacrificial feature and a second intermediate sacrificial feature disposed between the uppermost sacrificial feature and the first intermediate sacrificial feature. Each of the lowermost sacrificial feature and the first intermediate sacrificial feature includes the p-type dopant which includes boron, aluminum, gallium, indium, or combinations thereof, and the second intermediate sacrificial feature includes the n-type dopant which includes phosphorus, arsenic, antimony, or combinations thereof, so that one of the inner spacers formed to laterally cover the uppermost sacrificial feature has a thickness which is greater than a thickness of one of the inner spacers formed to laterally cover the first intermediate sacrificial feature and which is greater than a thickness of one of the inner spacers formed to laterally cover the lowermost sacrificial feature.

In accordance with some embodiments of the present disclosure, a semiconductor device includes a semiconductor substrate, a plurality of sets of channel features, an intermediate isolation feature, a gate feature, a first pair of inner spacers, a second pair of inner spacers, a lower source/drain portion, a middle isolation feature, and an upper source/drain portion. The sets of channel features are disposed on the semiconductor substrate in a first direction normal to the semiconductor substrate and are spaced apart from one another in a second direction parallel to the semiconductor substrate and transverse to the first direction. Each set of the channel features includes an uppermost channel feature and a lowermost channel feature disposed between the uppermost channel feature and the semiconductor substrate in the first direction. The intermediate isolation feature is disposed between the uppermost channel feature and the lowermost channel feature in the first direction and includes a first dielectric material. The gate feature includes a first gate portion disposed on the uppermost channel feature, a second gate portion disposed between the uppermost channel feature and the intermediate isolation feature, and a third gate portion disposed between the intermediate isolation feature and the lowermost channel feature. The first pair of inner spacers laterally covers the second gate portion and includes a second dielectric material different from the first dielectric material. The second pair of inner spacers laterally covers the third gate portion and includes a third dielectric material different from the first dielectric material. The lower source/drain portion is disposed on the semiconductor substrate and between two adjacent sets of the channel features. The middle isolation feature is disposed on the lower source/drain portion and is connected to the intermediate isolation feature. The upper source/drain portion is disposed on the middle isolation feature opposite to the lower source/drain portions.

In accordance with some embodiments of the present disclosure, the second dielectric material is different from the third dielectric material.

In accordance with some embodiments of the present disclosure, the first pair of inner spacers has a first thickness and the second pair of the inner spacers has a second thickness that is different from the first thickness.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of stack portions on a semiconductor substrate in a first direction normal to the semiconductor substrate, the stack portions being spaced apart from each other by a plurality of source/drain trenches which are disposed to alternate with the stack portions in a second direction parallel to the semiconductor substrate and transverse to the first direction, each of the stack portions including a set of channel features and a set of sacrificial features disposed to alternate with the set of the channel features in the first direction, the set of the channel features including a lowermost channel feature, an uppermost channel feature, and at least one intermediate channel feature disposed between the lowermost channel feature and the uppermost channel feature, the set of the sacrificial features including a lowermost sacrificial feature, an uppermost sacrificial feature, and at least one intermediate sacrificial feature disposed between the lowermost sacrificial feature and the uppermost sacrificial feature, the set of the channel features including a first semiconductor material, the set of the sacrificial features including a second semiconductor material different from the first semiconductor material, so as to permit each sacrificial feature of the set of the sacrificial features to have an etching selectivity that is greater than an etching selectivity of each channel feature of the set of the channel features, at least one sacrificial feature of the set of the sacrificial features including an n-type dopant, a p-type dopant, an impurity, or combinations thereof so as to permit one intermediate sacrificial feature of the set of the sacrificial features to have an etching selectivity that is greater than an etching selectivity of the other sacrificial features of the set of the sacrificial features;
forming a plurality of dummy poly gates on the stack portions, respectively;
removing the one intermediate sacrificial feature to form a gap between the lowermost sacrificial feature and the uppermost sacrificial feature of each of the stack portions;
removing two opposite side portions of each of the other sacrificial features of the set of the sacrificial features to form a plurality of recesses, each pair of the recesses being formed at two opposite sides of a corresponding one sacrificial feature of the other sacrificial features of the set of the sacrificial features;
forming an intermediate isolation feature to fill the gap;
forming a plurality of inner spacers to respectively fill the recesses;
forming a plurality of lower source/drain portions in the source/drain trenches, respectively;
forming a plurality of middle isolation features to cover the lower source/drain portions in the source/drain trenches, respectively; and
forming a plurality of upper source/drain portions to cover the middle isolation features in the source/drain trenches, respectively.

2. The method as claimed in claim 1, wherein the one intermediate sacrificial feature includes the n-type dopant which includes phosphorus, arsenic, antimony, or combinations thereof.

3. The method as claimed in claim 2, wherein the n-type dopant is formed as an n-type sacrificial sublayer in the one intermediate sacrificial feature.

4. The method as claimed in claim 1, wherein each of the other sacrificial features of the set of the sacrificial features includes the p-type dopant which includes boron, aluminum, gallium, indium, or combinations thereof.

5. The method as claimed in claim 4, wherein the p-type dopant is formed as a p-type sacrificial sublayer in each of the other sacrificial features of the set of the sacrificial features.

6. The method as claimed in claim 1, wherein the one intermediate sacrificial feature includes the n-type dopant which includes phosphorus, arsenic, antimony, or combinations thereof, and each of the other sacrificial features of the set of the sacrificial features includes the p-type dopant which includes boron, aluminum, gallium, indium, or combinations thereof.

7. The method as claimed in claim 6, wherein the p-type dopant is formed as a p-type sacrificial sublayer in each of the other sacrificial features of the set of the sacrificial features.

8. The method as claimed in claim 6, wherein the n-type dopant is formed as an n-type sacrificial sublayer in the one intermediate sacrificial feature.

9. The method as claimed in claim 1, wherein the gap is formed before formation of the recesses, so that the intermediate isolation feature is formed before formation of the inner spacers.

10. The method as claimed in claim 9, wherein the inner spacers and the intermediate isolation feature are made of different dielectric materials.

11. The method as claimed in claim 1, wherein each sacrificial feature of the set of the sacrificial features includes silicon germanium and the n-type dopant which includes boron, aluminum, gallium, indium or combinations thereof, a concentration of germanium in the one intermediate sacrificial feature being greater than a concentration of germanium in each sacrificial feature of the other sacrificial features of the set of the sacrificial features.

12. The method as claimed in claim 1, wherein the impurity includes carbon, nitrogen, oxygen, or combinations thereof.

13. A method for manufacturing a semiconductor device, comprising:
forming a plurality of stack portions on a semiconductor substrate in a first direction normal to the semiconductor substrate, the stack portions being spaced apart from each other by a plurality of source/drain trenches which are disposed to alternate with the stack portions in a second direction parallel to the semiconductor substrate and transverse to the first direction, each of the stack portions including a set of channel features and a set of sacrificial features disposed to alternate with the set of the channel features in the first direction, the set of the channel features including a lowermost channel feature, an uppermost channel feature, and at least one intermediate channel feature disposed between the lowermost channel feature and the uppermost channel feature, the set of the sacrificial features including a lowermost sacrificial feature, an uppermost sacrificial feature, and at least one intermediate sacrificial feature disposed between the lowermost sacrificial feature and the uppermost sacrificial feature, the set of the channel features including a first semiconductor material, the set of the sacrificial features including a second semiconductor material different from the first semiconductor material, so as to permit each sacrificial feature of the set of the sacrificial features to have an etching selectivity that is greater than an etching selectivity of each channel feature of the set of the channel features, at least one sacrificial feature of the set of the sacrificial features including an n-type dopant, a p-type dopant, an impurity, or combinations thereof so as to permit one intermediate sacrificial feature of the set of the sacrificial features to have an etching selectivity that is greater than an etching selectivity of the other sacrificial features of the set of the sacrificial features;
forming a plurality of dummy poly gates on the stack portions, respectively;
removing the one intermediate sacrificial feature to form a gap between the lowermost sacrificial feature and the uppermost sacrificial feature of each of the stack portions;
removing two opposite side portions of each of the other sacrificial features of the set of the sacrificial features to form a plurality of recesses, each pair of the recesses being formed at two opposite sides of a corresponding one sacrificial feature of the other sacrificial features of the set of the sacrificial features;
forming an intermediate isolation feature to fill the gap;
forming a plurality of inner spacers to respectively fill the recesses;
forming a plurality of lower source/drain portions in the source/drain trenches, respectively;
forming a plurality of middle isolation features to cover the lower source/drain portions in the source/drain trenches, respectively;
forming a plurality of upper source/drain portions to cover the middle isolation features in the source/drain trenches, respectively;
removing the dummy poly gates and the other sacrificial features of the set of the sacrificial features to form a plurality of cavities; and
forming a gate feature in each of the cavities.

14. The method as claimed in claim 13, wherein the gap and the recesses are formed simultaneously, so that the intermediate isolation feature and the inner spacers are formed simultaneously.

15. The method as claimed in claim 13, wherein each sacrificial feature of the other sacrificial features of the set of the sacrificial features includes the p-type dopant, the impurity, or a combination thereof, the p-type dopant including boron, aluminum, gallium, indium, or combinations thereof, the impurity including carbon, nitrogen, oxygen, or combinations thereof.

16. The method as claimed in claim 13, wherein each sacrificial feature of the other sacrificial features of the set of the sacrificial features includes the p-type dopant including boron, aluminum, gallium, indium, or combinations thereof, and a concentration of the p-type dopant in the uppermost sacrificial feature of the other sacrificial features of the set of the sacrificial features is higher than a concentration of the p-type dopant in remaining sacrificial features of the other sacrificial features of the set of the sacrificial features, so that one of the inner spacers formed to laterally cover the uppermost sacrificial feature has a thickness that is less than a thickness of each of the inner spacers formed to laterally cover the remaining sacrificial features of the other sacrificial features of the set of the sacrificial features.

17. The method as claimed in claim 13, wherein the at least one intermediate sacrificial feature includes a first intermediate sacrificial feature and a second intermediate sacrificial feature disposed between the uppermost sacrificial feature and the first intermediate sacrificial feature, each of the lowermost sacrificial feature and the first intermediate sacrificial feature including the p-type dopant which includes boron, aluminum, gallium, indium, or combinations thereof, the second intermediate sacrificial feature including the n-type dopant which includes phosphorus, arsenic, antimony, or combinations thereof, so that one of the inner spacers formed to laterally cover the uppermost sacrificial feature has a thickness which is greater than a thickness of one of the inner spacers formed to laterally cover the first intermediate sacrificial feature and which is greater than a thickness of one of the inner spacers formed to laterally cover the lowermost sacrificial feature.

18. A semiconductor device, comprising:
a semiconductor substrate;
a plurality of sets of channel features disposed on the semiconductor substrate in a first direction normal to the semiconductor substrate and spaced apart from one another in a second direction parallel to the semiconductor substrate and transverse to the first direction, each set of the channel features including an uppermost channel feature and a lowermost channel feature disposed between the uppermost channel feature and the semiconductor substrate in the first direction;
an intermediate isolation feature which is disposed between the uppermost channel feature and the lowermost channel feature in the first direction and which includes a first dielectric material;
a gate feature including a first gate portion disposed on the uppermost channel feature, a second gate portion disposed between the uppermost channel feature and the intermediate isolation feature, and a third gate portion disposed between the intermediate isolation feature and the lowermost channel feature;
a first pair of inner spacers laterally covering the second gate portion and including a second dielectric material different from the first dielectric material;
a second pair of inner spacers laterally covering the third gate portion and including a third dielectric material different from the first dielectric material;
a lower source/drain portion disposed on the semiconductor substrate and between two adjacent sets of the channel features;
a middle isolation feature disposed on the lower source/drain portion and connected to the intermediate isolation feature; and
an upper source/drain portion disposed on the middle isolation feature opposite to the lower source/drain portions.

19. The semiconductor device as claimed in claim 18, wherein the second dielectric material is different from the third dielectric material.

20. The semiconductor device as claimed in claim 18, wherein the first pair of inner spacers has a first thickness and the second pair of the inner spacers has a second thickness that is different from the first thickness.
